(19) United States
(12) Patent Application Publication
(10) Pub. No.: US 2026/0353741 A1
(43) Pub. Date: Nov. 5, 2026

(54) SEMICONDUCTOR STRUCTURES AND METHODS OF MAKING SAME

(71) Applicant: Taiwan Semiconductor Manufacturing Co., Ltd., Hsinchu (TW)

(72) Inventor: Han-Yeou Huang, Zhudong Township (TW)

(21) Appl. No.: 19/733,289

(22) Filed: Jul. 7, 2026

Related U.S. Application Data
(63) Continuation of application No. 18/884,860, filed on Sep. 13, 2024.
(60) Provisional application No. 63/655,678, filed on Jun. 4, 2024.

(51) Int. Cl. H10D 64/01; H10D 30/01; H10D 30/43; H10D 30/67; H10D 62/10; H10D 62/13; H10D 84/01; H10D 84/03; H10D 84/85; H10P 76/20

(52) U.S. Cl. CPC H10D 64/017; H10D 30/014; H10D 30/43; H10D 30/6735; H10D 30/6757; H10D 62/121; H10D 62/151; H10D 64/018; H10D 84/0167; H10D 84/017; H10D 84/038; H10D 84/85; H10P 76/2041

(57) ABSTRACT

A method includes removing first nanostructures from a plurality of nanostructures, the plurality of nanostructures comprising the first nanostructures alternatingly stacked with second nanostructures. After removing the first nanostructures, the method includes performing a trimming process on the second nanostructures, wherein the trimming process increases a curvature of at least a first corner of the second nanostructures. The method further includes forming a sacrificial material between the second nanostructures and replacing the sacrificial material with a gate stack.

### CROSS-REFERENCE TO RELATED APPLICATIONS

This application is a continuation of U.S. Application No. 18/884,860, filed on Sep. 13, 2024, which claims priority to U.S. Provisional Application No. 63/655,678, filed on Jun. 4, 2024, which applications are hereby incorporated by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nano-FET) in a three-dimensional view, in accordance with some embodiments.

FIGS. 2, 3, 4, 5A, 5B, 6A, 6B, 6C, 7A, 7B, 7C, 8A, 8B, 9A, 9B, 10A, 10B, 10C, 10D, 11A, 11B, 11C, 11D, 12A, 12B, 13A, 13B, 14A, 14B, 15A, 15B, 15C, 15D, 15E, 15F, 16A, 16B, 16C, 16D, 17A, 17B, 17C, 18A, 18B, 19A, 19B, and 19C illustrate varying views of intermediary steps of manufacturing a nano-FET transistor, in accordance with some embodiments.

FIGS. 20A, 20B, 21A, 21B, 22A, 22B, 22C, 22D, 22E, 22F, 22G, 22H, 23A, 23B, 24A, 24B, 25A, 25B, and 25C illustrate varying views of intermediary steps of manufacturing a nano-FET transistor, in accordance with some embodiments.

FIG. 26 illustrates a semiconductor package in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In various embodiments, forming nano-FETs includes forming first nanostructures and second nanostructures that are alternatingly stacked. Subsequently, the second nanostructures are replaced with a gate stack that surrounds the first nanostructures. Replacing the second nanostructures can include removing the second nanostructures to define openings between the first nanostructures, depositing a sacrificial material in the openings between the first nanostructures, and then replacing the sacrificial material with the gate stack. Removing the second nanostructures may leave a residue (impurities) on surfaces of the first nanostructures, and various embodiments may include trimming the first nanostructures to remove the impurities. As a result, device performance in the resulting nano-FETs can be improved (e.g., increased carrier mobility, reduced channel resistance, or the like).

Trimming the first nanostructures may further round corner regions (e.g., increase a curvature) of the first nanostructures. For example, the first nanostructures may have vertical and/or horizontal radii in a range of 0.9 nm to 2 nm after trimming. It has been observed that the rounded corners, particularly having radii in the above ranges, increase a deposition window of the gate stack. As a result, improved gate electrode gap fill between the first nanosheets can be achieved, gaps in the gate stack can be reduced, and high-k gate dielectric damage (e.g., damage over time due to corona discharge) can be reduced.

Embodiments are described below in a particular context, a die comprising nano-FETs. Various embodiments may be applied, however, to dies comprising other types of transistors (e.g., stacking transistors, or the like) in lieu of or in combination with the nano-FETs.

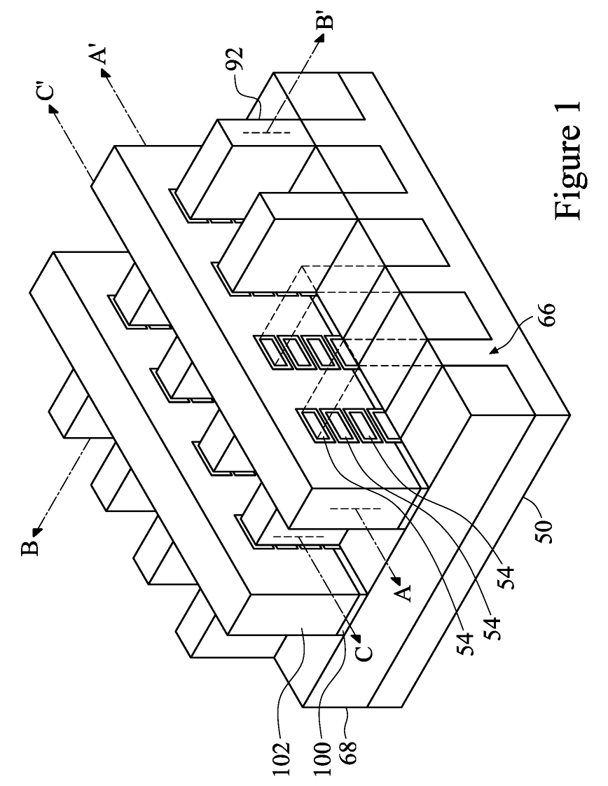

FIG. 1 illustrates an example of nano-FETs (e.g., nanowire FETs, nanosheet FETs, or the like) in a three-dimensional view, in accordance with some embodiments. Certain features are simplified and/or omitted in FIG. 1 for ease of illustration. The nano-FETs comprise nanostructures 54 (e.g., nanosheets, nanowire, or the like) over fins 66 on a substrate 50 (e.g., a semiconductor substrate), wherein the nanostructures 54 act as channel regions for the nano-FETs. The nanostructure 54 may include p-type nanostructures, n-type nanostructures, or a combination thereof. Shallow trench isolation (STI) regions 68 (also referred to as STI structures or STI regions) are disposed between adjacent fins 66, which may protrude above and from between neighboring STI regions 68. Although the STI regions 68 is described/illustrated as being separate from the substrate 50, as used herein, the term “substrate” may refer to the semiconductor substrate alone or a combination of the semiconductor substrate and the isolation regions. Additionally, although a bottom portion of the fins 66 are illustrated as being single, continuous materials with the substrate 50, the bottom portion of the fins 66 and/or the substrate 50 may comprise a single material or a plurality of materials. In this context, the fins 66 refer to the portion extending between the neighboring STI regions 68.

Gate dielectric layers 100 are over top surfaces of the fins 66 and along top surfaces, sidewalls, and bottom surfaces of the nanostructures 54. Gate electrodes 102 are over the gate dielectric layers 100. Epitaxial source/drain regions 92 are disposed on the fins 66 on opposing sides of the gate dielectric layers 100 and the gate electrodes 102. Source/drain region(s) 92 may refer to a source or a drain, individually or collectively dependent upon the context.

FIG. 1 further illustrates reference cross-sections that are used in later figures. Cross-section A-A’ is along a longitudinal axis of a gate electrode 102 and in a direction, for example, perpendicular to the direction of current flow between the epitaxial source/drain regions 92 of a nano-FET. Cross-section B-B’ is perpendicular to cross-section A-A’ and is parallel to a longitudinal axis of a fin 66 of the nano-FET and in a direction of, for example, a current flow between the epitaxial source/drain regions 92 of the nano-FET. Cross-section C-C’ is parallel to cross-section A-A’ and extends through epitaxial source/drain regions of the nano-FETs. Subsequent figures refer to these reference cross-sections for clarity.

Some embodiments discussed herein are discussed in the context of nano-FETs formed using a gate-last process. In other embodiments, a gate-first process may be used. Also, some embodiments contemplate aspects used in planar devices, such as planar FETs or in fin field-effect transistors (FinFETs).

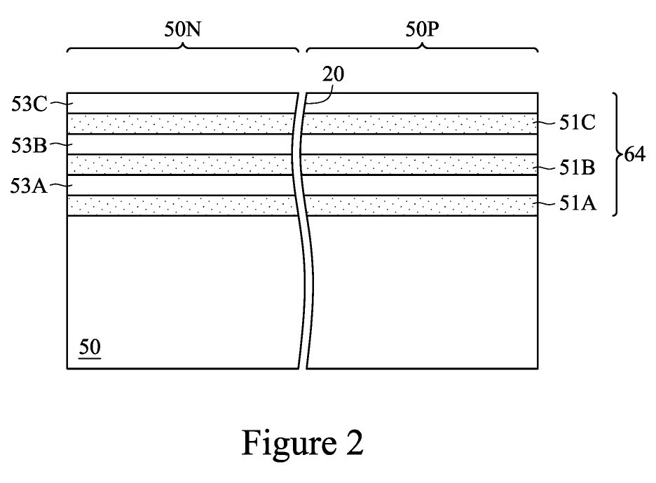

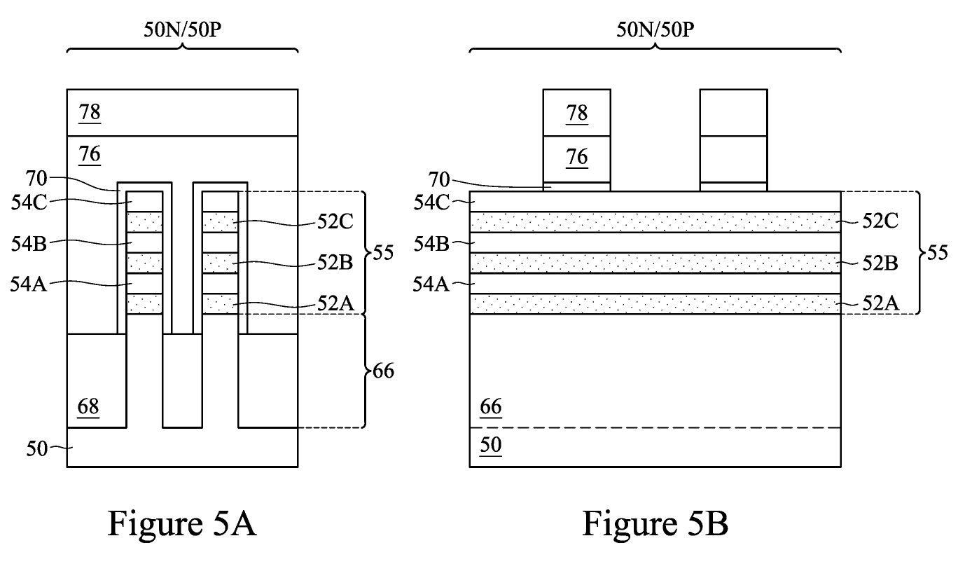

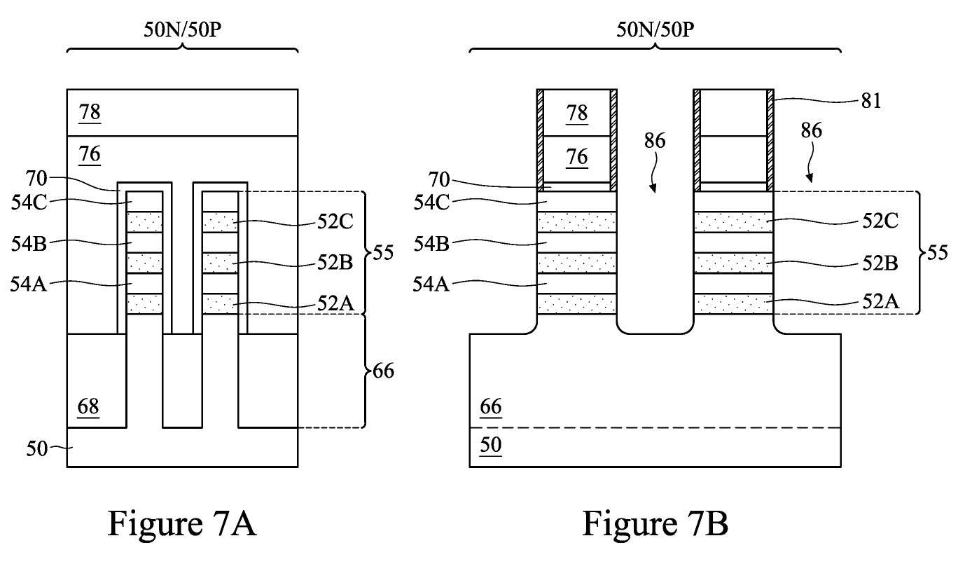

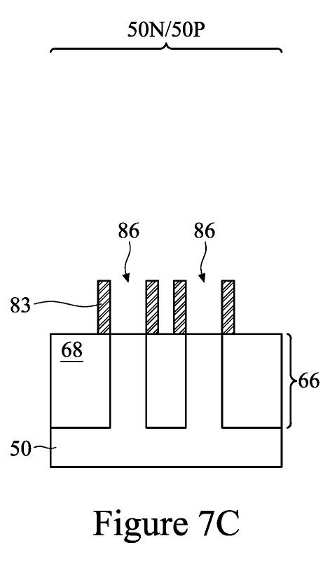

FIGS. 2-21C are cross-sectional views of intermediate stages in the manufacturing of nano-FETs, in accordance with some embodiments. FIGS. 2, 3, 4, 5A, 6A, 7A, 8A, 9A, 10A, 11A, 12A, 13A, 14A, 15A, 15C, 15D, 15E, 16A, 16C, 17A, 18A, and 19A illustrate reference cross-section A-A’ illustrated in FIG. 1. FIGS. 5B, 6B, 6C, 7B, 8B, 9B, 10B, 10C, 10D, 11B, 12B, 13B, 14B, 15B, 15F, 16B, 16D, 17B, 18B, 18C, and 19B illustrate reference cross-section B-B’ illustrated in FIG. 1. FIGS. 7C, 11C, 11D, 17C, and 19C illustrate reference cross-section C-C’ illustrated in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided. Subsequent figures describe processing steps that may be performed in either the n-type regions 50N or the p-type regions 50P unless otherwise noted.

Further in FIG. 2, a multi-layer stack 64 is formed over the substrate 50. The multi-layer stack 64 includes alternating layers of first semiconductor layers 51A-C (collectively referred to as first semiconductor layers 51) and second semiconductor layers 53A-C (collectively referred to as second semiconductor layers 53). For purposes of illustration and as discussed in greater detail below, the first semiconductor layers 51 will be removed and the second semiconductor layers 53 will be patterned to form channel regions of nano-FETs in both the n-type region 50N and the p-type region 50P. Nevertheless, in some embodiments, the second semiconductor layers 53 may be removed and the first semiconductor layers 51 may be patterned to form channel regions of nano-FETs in both the n-type region 50N and the p-type region 50P. For example, the channel regions in both the n-type region 50N and the p-type region 50P may have a same material composition (e.g., silicon, or another semiconductor material) and be formed simultaneously.

In other embodiments, the first semiconductor layers 51 may be removed and the second semiconductor layers 53 may be patterned to form channel regions of nano-FETs in the p-type region 50P, and the second semiconductor layers 53 may be removed and the first semiconductor layers 51 may be patterned to form channel regions of nano-FETs in the n-type region 50N. In still other embodiments, the first semiconductor layers 51 may be removed and the second semiconductor layers 53 may be patterned to form channel regions of nano-FETs in the n-type region 50N, and the second semiconductor layers 53 may be removed and the first semiconductor layers 51 may be patterned to form channel regions of nano-FETs in the p-type region 50P. In such embodiments, the channel regions of the n-type region 50N may have a different material composition than the channel regions of the p-type region 50P. The first semiconductor layers 51 and the second semiconductor layers 53 may be selectively removed from each of the n-type region 50N and p-type region 50P through additional masking and etching steps. For example, the channel regions of the n-type region 50N may be silicon channel regions while the channel regions of the p-type region 50P may be silicon germanium channel regions.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like.

In various embodiments, the first semiconductor layers 51 may be formed of a first semiconductor material, such as silicon germanium, or the like, and the second semiconductor layers 53 may be formed of a second semiconductor material, such as silicon, silicon carbon, or the like. The first semiconductor materials and the second semiconductor materials may be materials having a high-etch selectivity to one another. As such, the first semiconductor layers 51 of the first semiconductor material may be removed without significantly removing the second semiconductor layers 53 of the second semiconductor material, thereby allowing the second semiconductor layers 53 to be patterned to form channel regions of the nano-FETs.

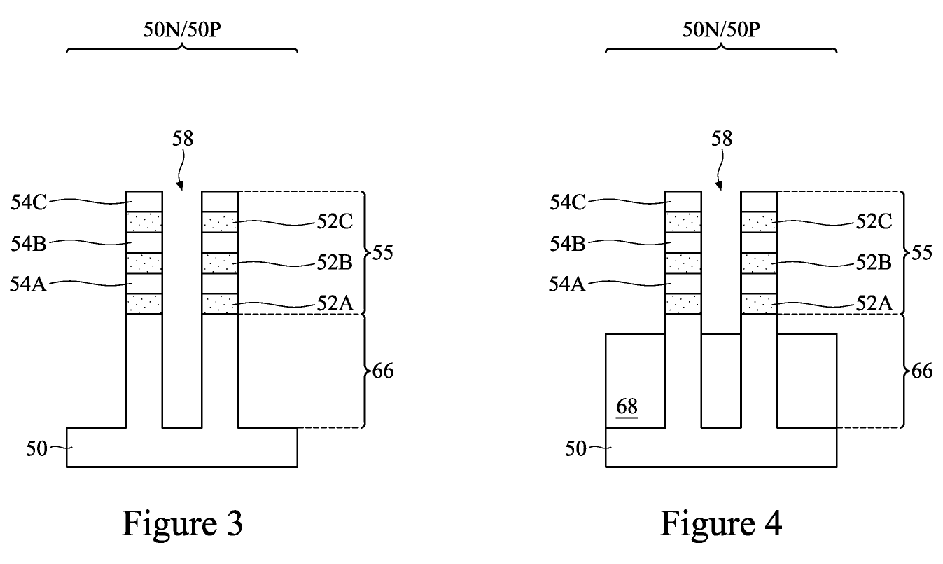

Referring now to FIG. 3, fins 66 are formed in the substrate 50 and nanostructures 55 are formed in the multi-layer stack 64, in accordance with some embodiments. In some embodiments, the nanostructures 55 and the fins 66 may be formed in the multi-layer stack 64 and the substrate 50, respectively, by etching trenches 58 in the multi-layer stack 64 and the substrate 50. The etching may be any acceptable etch process, such as a reactive ion etch (RIE), neutral beam etch (NBE), the like, or a combination thereof. The etching may be anisotropic. During the etching process, a hard mask may be used to define a pattern of the fins 66 and the nanostructures 55. The hard mask may comprise any suitable insulating material, such as an oxide, a nitride, and oxynitride, and oxycarbonitride, or the like. In some embodiments (not separately illustrated), the hard mask may be a multi-layer structure. The hard mask may be formed over the nanostructures 55 using an acceptable process(es) such as thermal oxidation, physical vapor deposition (PVD), CVD, ALD, combinations thereof, or the like.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, a sacrificial layer is formed over a substrate and patterned using a photolithography process. Spacers are then formed alongside the patterned sacrificial layer using a self-aligned process. The sacrificial layer is then removed, and the remaining spacers may then be used to pattern the fins 66 and the nanostructures 55.

Forming the nanostructures 55 by etching the multi-layer stack 64 may further define first nanostructures 52A-C (collectively referred to as the first nanostructures 52) from the first semiconductor layers 51 and define second nanostructures 54A-C (collectively referred to as the second nanostructures 54) from the second semiconductor layers 53. The first nanostructures 52 and the second nanostructures 54 may further be collectively referred to as the nanostructures 55.

FIG. 3 illustrates the fins 66 having substantially equal widths for illustrative purposes. In some embodiments, widths of the fins 66 in the n-type region 50N may be greater or thinner than the fins 66 in the p-type region 50P. Further, while FIG. 3 illustrates each of the fins 66 and the nanostructures 55 as having a consistent width throughout, in other embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape.

In FIG. 4, shallow trench isolation (STI) regions 68 are formed adjacent the fins 66. The STI regions 68 may be formed by depositing an insulation material over the substrate 50, the fins 66, and nanostructures 55, and between adjacent fins 66 to fill the trenches 58. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 55. Although the insulation material is illustrated as a single layer, some embodiments may utilize multiple layers. For example, in some embodiments a liner (not separately illustrated) may first be formed along a surface of the substrate 50, the fins 66, and the nanostructures 55. Thereafter, a fill material, such as those discussed above may be formed over the liner.

A removal process is then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material are level after the planarization process is complete.

The insulation material is then recessed to form the STI regions 68. The insulation material is recessed such that upper portions of fins 66 protrude from between neighboring STI regions 68. Further, the top surfaces of the STI regions 68 may have a flat surface as illustrated, a convex surface, a concave surface (such as dishing), or a combination thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the fins 66 and the nanostructures 55). For example, an oxide removal using, for example, dilute hydrofluoric (dHF) acid may be used. Thereafter, an optional hard mask (not separately illustrated) may then be formed over a top surface of the STI regions 68 to cover the STI regions 68. The hard mask may be made of a nitride or other material that has etch selectivity to the STI regions 68 (e.g., etch selectivity to a fill material of the STI regions 68).

Further in FIG. 4, appropriate wells (not separately illustrated) may be formed in the fins 66 and/or the nanostructures 55. In embodiments with different well types, different implant steps for the n-type region 50N and the p-type region 50P may be achieved using a photoresist or other masks (not separately illustrated). For example, a photoresist may be formed over the fins 66 and the nanostructures 55 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other masks (not separately illustrated) is formed over the fins 66 and the nanostructures 55 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

In FIGS. 5A and 5B, dummy gates 76 are formed over and along sidewalls of the nanostructures 55 and the fin 66. To form the dummy gates 76, first, a dummy dielectric layer is formed on the fins 66 and/or the nanostructures 55. The dummy dielectric layer may be, for example, silicon oxide, silicon nitride, a combination thereof, or the like, and may be deposited or thermally grown according to acceptable techniques. A dummy gate layer is formed over the dummy dielectric layer, and a mask layer is formed over the dummy gate layer. The dummy gate layer may be deposited over the dummy dielectric layer and then planarized, such as by a CMP. The mask layer may be deposited over the dummy gate layer. The dummy gate layer may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer may be deposited by physical vapor deposition (PVD), CVD, sputter deposition, or other techniques for depositing the selected material. The dummy gate layer may be made of other materials that have a high etching selectivity from the etching of isolation regions. The mask layer may include, for example, silicon nitride, silicon oxynitride, or the like.

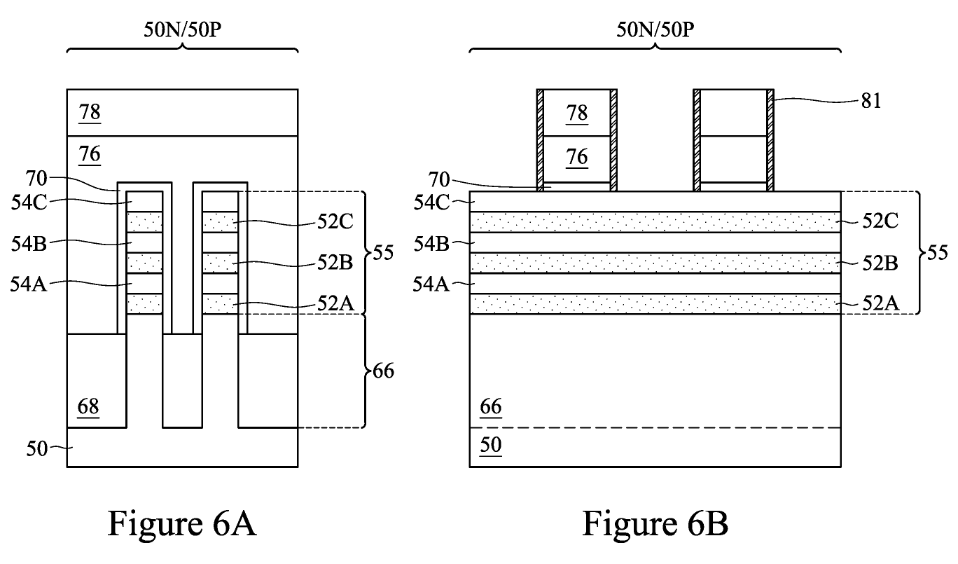

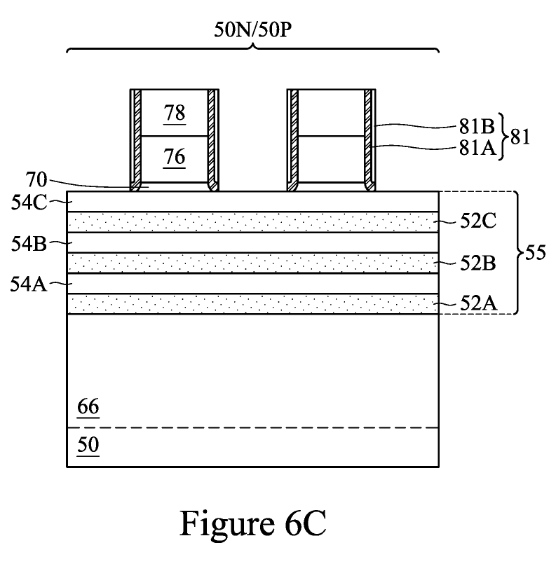

Subsequently, the mask layer may be patterned using acceptable photolithography and etching techniques to form masks 78. The pattern of the masks 78 then may be transferred to the dummy gate layer and to the dummy dielectric layer to form dummy gates 76 and dummy gate dielectrics 70, respectively. The dummy gates 76 cover respective channel regions of the fins 66. The pattern of the masks 78 may be used to physically separate each of the dummy gates 76 from adjacent dummy gates 76. The dummy gates 76 may also have a lengthwise direction substantially perpendicular to the lengthwise direction of respective fins 66. It is noted that the dummy gate dielectrics 70 is shown covering only the fins 66 and the nanostructures 55 for illustrative purposes only. In some embodiments, the dummy gate dielectrics 70 may be deposited such that the dummy gate dielectrics 70 covers the STI regions 68, such that the dummy gate dielectrics 70 extends between the dummy gates 76 and the STI regions 68. Patterning the dummy gates 76 and the dummy gate dielectrics 70 can result in any suitable sidewall profile. For example, the dummy gates 76 and the dummy gate dielectrics 70 can have straight sidewalls as illustrated by FIG. 5B, or curved sidewalls as illustrated by FIG. 6C. Specifically, bottom regions of the dummy gates 70 and the dummy gate dielectrics 76 may include rounded, concave sidewalls.

In FIGS. 6A and 6B, gate spacers 81 are formed over the nanostructures 55 and the STI regions 68, on exposed sidewalls of the masks 78 (if present), the dummy gates 76, and the dummy gate dielectrics 70. The gate spacers 81 may be formed by conformally forming one or more dielectric material(s) and subsequently etching the dielectric material(s). Acceptable dielectric materials may include silicon oxide, silicon nitride, silicon oxynitride, silicon oxycarbonitride, or the like, which may be formed by a deposition process such as chemical vapor deposition (CVD), atomic layer deposition (ALD), or the like. Other insulation materials formed by any acceptable process may be used. Any acceptable etch process, such as a dry etch, a wet etch, the like, or a combination thereof, may be performed to pattern the dielectric material(s). The etching may be anisotropic. The dielectric material(s), when etched, have portions left on the sidewalls of the dummy gates 76 (thus forming the gate spacers 81). As subsequently described in greater detail, the dielectric material(s), when etched, may also have portions left on the sidewalls of the semiconductor fins 66 and/or the nanostructures 55 (thus forming fin spacers 83, see FIG. 7C). After etching, the fin spacers 83 and/or the gate spacers 81 can have straight sidewalls (as illustrated) or can have curved sidewalls (not separately illustrated).

Although FIG. 6B illustrates the gate spacers 81 as being a single layer, the gate spacers 81 may be a multi-layer structure in other embodiments. For example, FIG. 6C illustrates the gate spacers 81 is a multi-layer structure including first gate spacers 81A and second gate spacers 81B over the first gate spacers 81A. The first gate spacers 81A and second gate spacers 81B may be formed by conformally forming at least two dielectric materials and subsequently etching the dielectric materials. Acceptable dielectric materials may include silicon oxide, silicon nitride, silicon oxynitride, silicon oxycarbonitride, or the like, which may be formed by a deposition process such as CVD, ALD, or the like. The first gate spacers 81A and second gate spacers 81B may be made of different materials that can be selectively etched relative to each other. For example, the first gate spacers 81A may be made of an oxide, or the like while the second gate spacers 81B may be made of a nitride. Other combinations of insulation materials formed by any acceptable process may be used. Any acceptable etch process, such as a dry etch, a wet etch, the like, or a combination thereof, may be performed to pattern the dielectric material(s). The etching may be anisotropic. The dielectric material(s), when etched, have L-shaped portions left on the sidewalls of the dummy gates 76 (thus forming the first gate spacers 81A) and portions over the L-shaped portions (thus forming the second gate spacers 81B).

Further, implants for lightly doped source/drain (LDD) regions (not separately illustrated) may be performed. The LDD implants may be performed before the gate spacers 81 are formed. In embodiments with different device types, similar to the implants for the previously described wells, a mask, such as a photoresist, may be formed over the n-type region 50N, while exposing the p-type region 50P, and appropriate type (e.g., p-type) impurities may be implanted into the semiconductor fins 66 and the nanostructures 55 exposed in the p-type region 50P. The mask may then be removed. Subsequently, a mask, such as a photoresist, may be formed over the p-type region 50P while exposing the n-type region 50N, and appropriate type impurities (e.g., n-type) may be implanted into the semiconductor fins 66 and the nanostructures 55 exposed in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from about 10¹⁵ atoms/cm³ to about 10¹⁹ atoms/cm³. An anneal may be used to repair implant damage and to activate the implanted impurities.

It is noted that the previous disclosure generally describes a process of forming spacers and LDD regions. Other processes and sequences may be used. For example, fewer or additional spacers may be utilized, different sequence of steps may be utilized, additional spacers may be formed and removed, and/or the like. Furthermore, the n-type devices and the p-type devices may be formed using different structures and steps.

In FIGS. 7A-7C, first recesses 86 are formed in the fins 66, the nanostructures 55, and the substrate 50, in accordance with some embodiments. Epitaxial source/drain regions will be subsequently formed in the first recesses 86. The first recesses 86 may extend through the first nanostructures 52 and the second nanostructures 54, and into the substrate 50. As illustrated in FIG. 7C, top surfaces of the STI regions 68 may be level with bottom surfaces of the first recesses 86. In other embodiments, the fins 66 may be etched such that bottom surfaces of the first recesses 86 are disposed above or below the top surfaces of the STI regions 68. The first recesses 86 may be formed by etching the fins 66, the nanostructures 55, and the substrate 50 using anisotropic etching processes, such as RIE, NBE, or the like. The gate spacers 81, the fin spacers 83, and the masks 78 mask portions of the fins 66, the nanostructures 55, and the substrate 50 during the etching processes used to form the first recesses 86. A single etch process or multiple etch processes may be used to etch each layer of the nanostructures 55 and/or the fins 66. Timed etch processes may be used to stop the etching of the first recesses 86 after the first recesses 86 reach a desired depth.

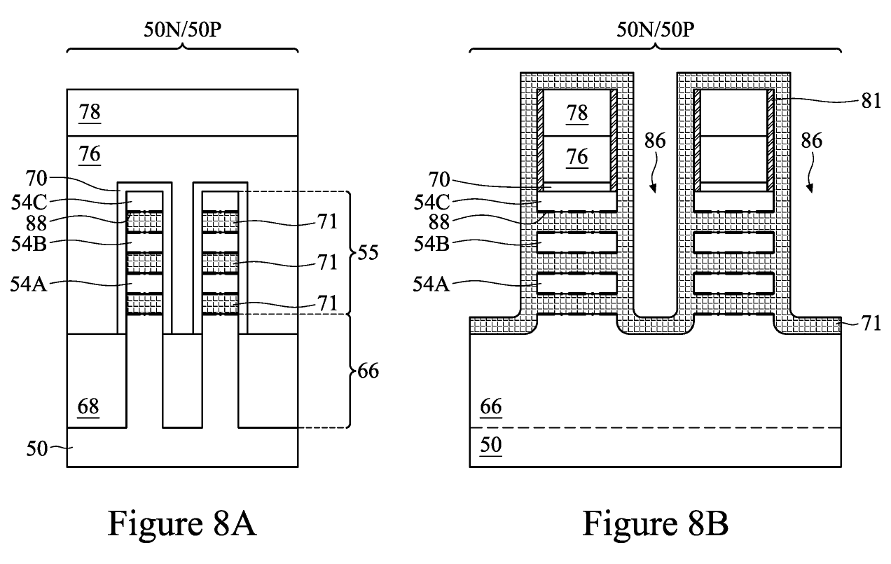

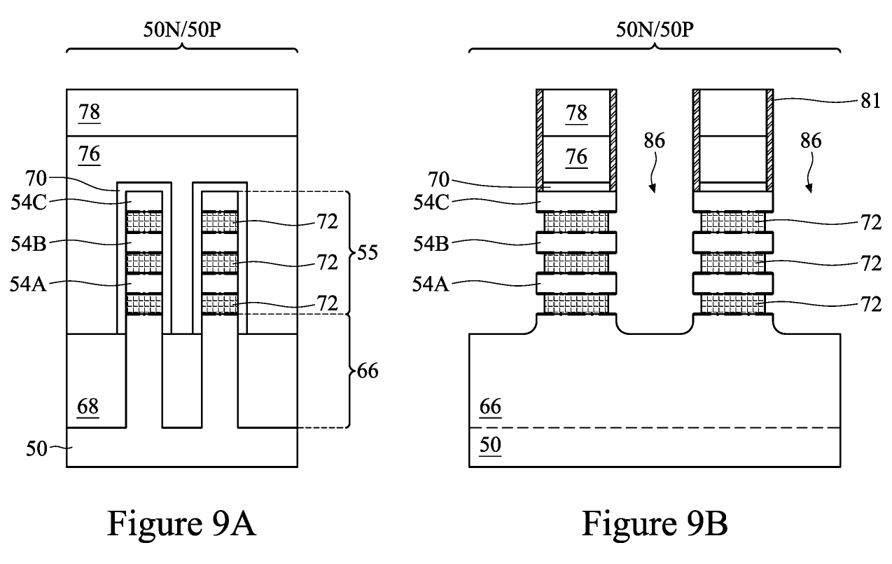

In FIGS. 8A-9B, the first nanostructures 52 are replaced with a sacrificial material 72 (also referred to as disposable oxide interposers (DOI) 72). Referring first to FIGS. 8A and 8B, replacing the first nanostructures 52 may include etching away the first nanostructures 52 using a suitable etch process, such as an isotropic etch process, that is performed through the first recesses 86. The etch process may be selective to the material of the first nanostructures 52 and may remove the first nanostructures 52 without significantly removing the second nanostructures 54 or the semiconductor fins 66. In an embodiment in which the first nanostructures 52 include, e.g., SiGe, and the second nanostructures 54 include, e.g., Si or SiC, a dry etch process with tetramethylammonium hydroxide (TMAH), ammonium hydroxide (NH₄OH), or the like may be used to remove the first nanostructures 52. Removing the first nanostructures 52 may leave impurities 88 on surfaces of the second nanostructures 54 in regions where the first nanostructures 52 were removed, such as within the first recesses 86. The impurities 88 may include elements of the first nanostructures 52 (e.g., germanium when the first nanostructures 52 include SiGe) and/or residue from the etching process used to remove the first nanostructures 52.

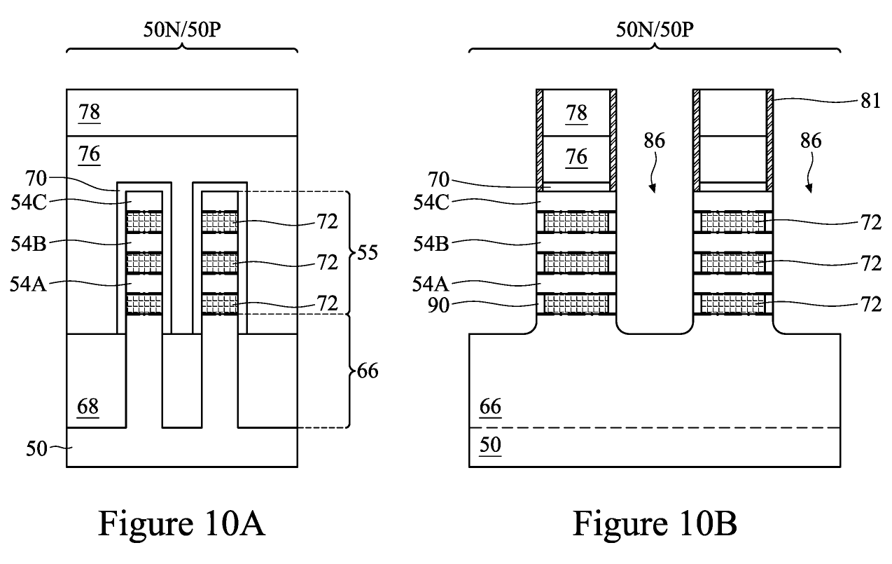

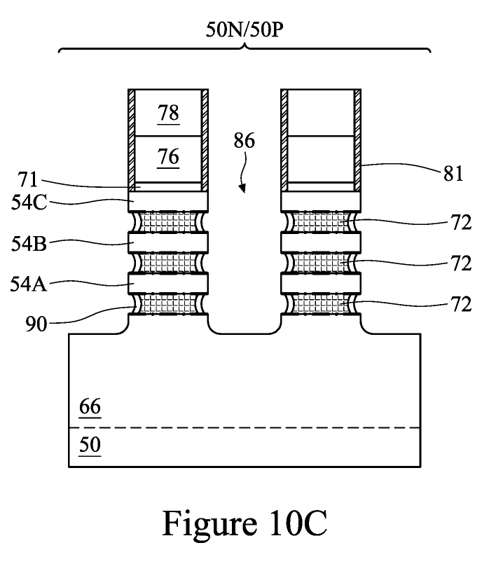

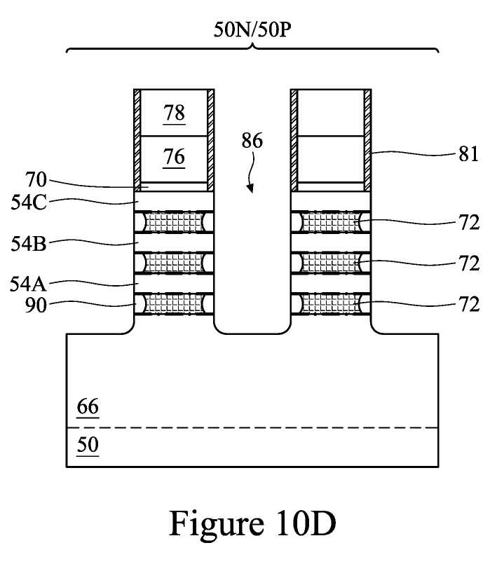

Subsequently, a sacrificial material layer 71 is deposited in the first recesses 86 and spaces where the first nanostructures 52 were removed. The sacrificial material layer 71 may be deposited by a conformal deposition process, such as CVD, ALD, or the like. The sacrificial material layer may comprise an insulating material such as silicon oxide (e.g., SiO₂), or the like that can be selectively etched from the second nanostructures 54. In FIGS. 9A and 9B, the sacrificial material layer 71 may then be etched to form the sacrificial material 72. The etching may be isotropic or anisotropic. For example, the sacrificial material layer may be etched by a wet etch process using diluted HF, or the like as an etchant. In some embodiments, the etching is performed until sidewalls of the sacrificial material 72 is recessed past sidewalls of the nanostructures 54. Although sidewalls of sacrificial material 72 are illustrated as being straight in FIG. 9B, the sidewalls may be concave or convex (see e.g., FIG. 10C). Because the impurities 88 remain on surfaces of the nanostructures 54 on which the sacrificial material layer 71 is deposited, the impurities 88 may be disposed at an interface between the second nanostructures 54 and the sacrificial material 72.

Replacing the first nanostructures 52 with the sacrificial material 72 may provide advantages. For example, in subsequent source/drain formation steps, one or more high temperature processes may be performed to activate the dopants in the source/drain regions. When the material of the first nanostructures 52 (e.g., SiGe) is exposed to high temperatures, germanium intermixing and increased roughness at an interfaces between the nanostructures 52 and 54 may result. Such manufacturing defects may degrade the performance of the resulting transistor devices. For example, when germanium diffuses into the second nanostructures 54, germanium residue may remain in channel regions of the resulting transistor devices, which negatively affects the performance of the channel regions. By replacing the first nanostructures 52 with an insulating material (the sacrificial material 72) prior to the high temperature processes (e.g., source/drain annealing), manufacturing defects can be reduced and device performance can be improved (e.g., increased current drive, reduced capacitance, and improved short channel effect).

In FIGS. 10A and 10B, inner spacers 90 are formed in the first recesses 86 on the sidewalls of the sacrificial material 72. The inner spacers 90 may be formed between the second nanostructures 54, and the impurities 88 may be disposed an at interface between the inner spacers 90 and the second nanostructures 54. The inner spacers 90 act as isolation features between subsequently formed source/drain regions and a gate structure. As will be discussed in greater detail below, source/drain regions will be formed in the first recesses 86, while the sacrificial material 72 will be replaced with corresponding gate structures. The inner spacers 90 may also be used to prevent damage to subsequently formed source/drain regions by subsequent etching processes, such as etching processes used to form gate structures.

The inner spacers 90 may be formed by depositing an inner spacer layer (not separately illustrated) over the structures illustrated in FIGS. 9A and 9B. The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the inner spacers 90. The inner spacer layer may be etched by an anisotropic etching process, such as RIE, NBE, or the like.

Although FIG. 10B illustrates outer sidewalls of the inner spacers 90 as being flush with sidewalls of the second nanostructures 54, the outer sidewalls of the inner spacers 90 may extend beyond or be recessed from sidewalls of the second nanostructures 54 (see e.g., FIG. 10C). Moreover, although the outer sidewalls of the inner spacers 90 are illustrated as being straight in FIG. 10B, the outer sidewalls of the inner spacers 90 may be concave or convex. As an example, FIG. 10C illustrates an embodiment in which sidewalls of the sacrificial material 72 are concave, outer sidewalls of the inner spacers 90 are concave, and the inner spacers 90 are recessed from sidewalls of the second nanostructures 54. Other configurations are also possible. For example, FIG. 10D illustrates an embodiment in which sidewalls of the sacrificial material 72 are concave, outer sidewalls of the inner spacers 90 are straight, and the inner spacers 90 are flush with sidewalls of the second nanostructures 54.

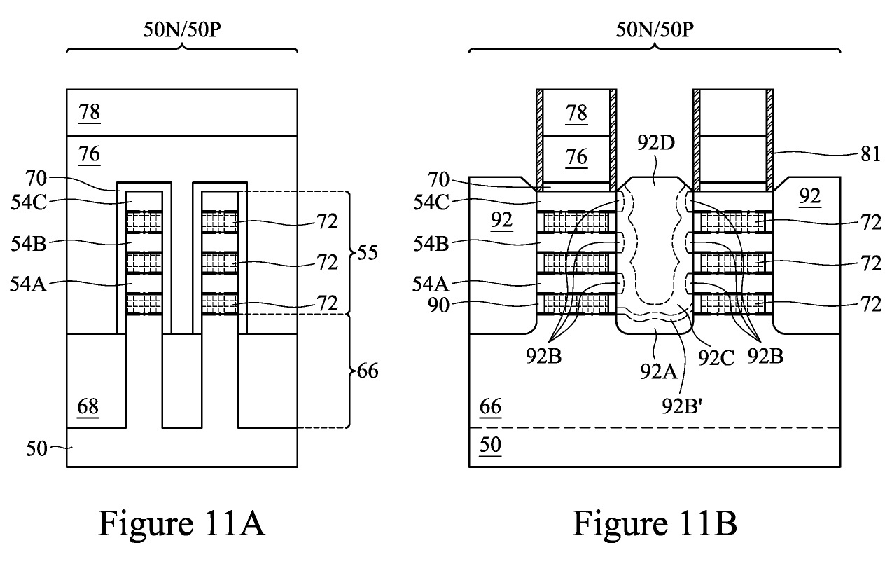

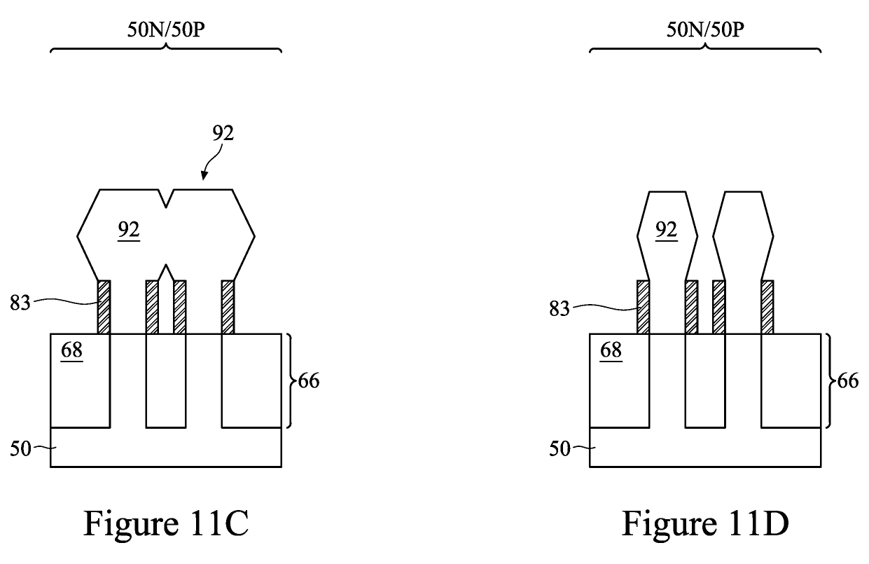

In FIGS. 11A-11D, epitaxial source/drain regions 92 are formed in the first recesses 86. In some embodiments, the source/drain regions 92 may exert stress on the second nanostructures 54 in the n-type region 50N and/or the p-type region 50P, thereby improving performance. As illustrated in FIG. 11B, the epitaxial source/drain regions 92 are formed in the first recesses 86 such that each dummy gate 76 is disposed between respective neighboring pairs of the epitaxial source/drain regions 92. In some embodiments, the gate spacers 81 are used to separate the epitaxial source/drain regions 92 from the dummy gates 76 and the inner spacers 90 are used to separate the epitaxial source/drain regions 92 from the sacrificial material 72 by an appropriate lateral distance so that the epitaxial source/drain regions 92 do not short out with subsequently formed gates of the resulting nano-FETs.

The epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the first recesses 86 in the n-type region 50N. The epitaxial source/drain regions 92 may include any acceptable material appropriate for n-type nano-FETs. For example, if the second nanostructures 54 are silicon, the epitaxial source/drain regions 92 in the n-type region 50N may include materials exerting a tensile strain on the second nanostructures 54, such as silicon, silicon carbide, phosphorous doped silicon carbide, silicon phosphide, or the like.

The epitaxial source/drain regions 92 in the p-type region 50P, e.g., the PMOS region, may be formed by masking the n-type region 50N, e.g., the NMOS region. Then, the epitaxial source/drain regions 92 are epitaxially grown in the first recesses 86 in the p-type region 50P. The epitaxial source/drain regions 92 may include any acceptable material appropriate for p-type nano-FETs. For example, if the second nanostructures 54 are silicon, the epitaxial source/drain regions 92 in the p-type region 50P may include materials exerting a compressive strain on the second nanostructures 54, such as silicon-germanium, boron doped silicon-germanium, germanium, germanium tin, or the like.

The epitaxial source/drain regions 92, the second nanostructures 54, and/or the substrate 50 may be implanted with dopants to form source/drain regions, similar to the process previously discussed for forming lightly-doped source/drain regions, followed by an anneal. The source/drain regions may have an impurity concentration of between about 1x10¹⁹ atoms/cm³ and about 1x10²¹ atoms/cm³. The n-type and/or p-type impurities for source/drain regions may be any of the impurities previously discussed. In some embodiments, the epitaxial source/drain regions 92 may be in situ doped during growth.

As a result of the epitaxy processes used to form the epitaxial source/drain regions 92 in the n-type region 50N and the p-type region 50P, upper surfaces of the epitaxial source/drain regions 92 have facets which expand laterally outward beyond sidewalls of the nanostructures 55. In some embodiments, these facets cause adjacent epitaxial source/drain regions 92 of a same nano-FET to merge as illustrated by FIG. 11C. In other embodiments, adjacent epitaxial source/drain regions 92 remain separated after the epitaxy process is completed as illustrated by FIG. 11D. In the embodiments illustrated in FIGS. 11C and 11D, the fin spacers 83 may be formed on top surfaces of the STI regions 68, thereby blocking the epitaxial growth. In some other embodiments, the fin spacers 83 may cover portions of the sidewalls of the nanostructures 55 further blocking the epitaxial growth. In some other embodiments, the spacer etch used to form the fin spacers 83 may be adjusted to remove the spacer material to allow the epitaxially grown region to extend to the surface of the STI structures 68.

The epitaxial source/drain regions 92 may comprise one or more semiconductor material layers. For example, the epitaxial source/drain regions 92 may comprise a first semiconductor material layer 92A, a second semiconductor material layer 92B, a third semiconductor material layer 92C, and a fourth semiconductor material 92D. Any number of semiconductor material layers may be used for the epitaxial source/drain regions 92.

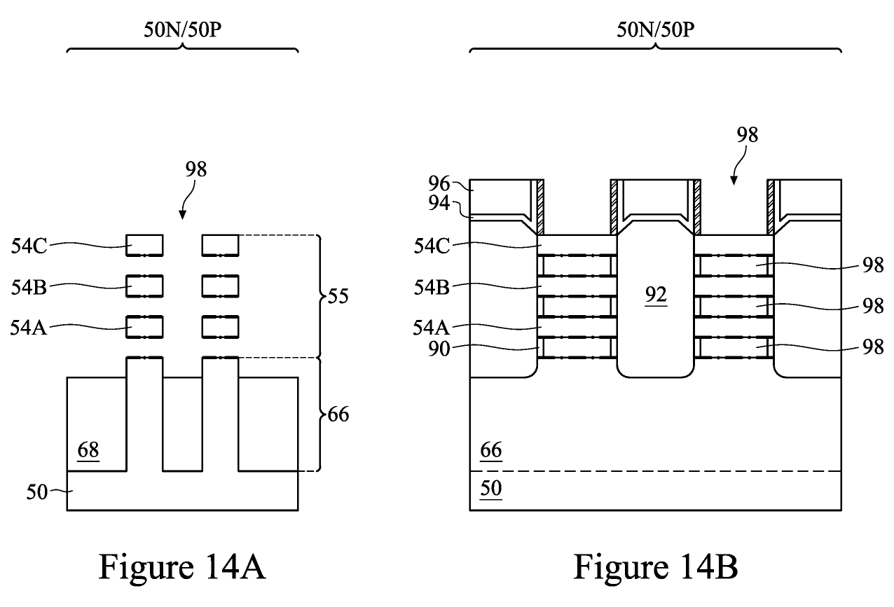

Each of the first semiconductor material layer 92A, the second semiconductor material layer 92B, the third semiconductor material layer 92C, and the fourth semiconductor material layer 92D may be formed of different semiconductor materials and may be doped to different dopant concentrations. For example, the first semiconductor material layer 92A may be a undoped or lightly doped layer that prevents or reduces diffusion of dopants from the overlying epitaxial layers (e.g., particularly the third and fourth semiconductor material layers 92C and 92D) into the underlying substrate 50. In a specific example, the first and second semiconductor material layers 92A and 92B may be silicon layers that are substantially free of germanium, and the third and fourth semiconductor material layers 92C and 92D may be silicon germanium layers. The second semiconductor material layer 92B may be high concentration, dopant layer that is formed to increase etch selectivity along sidewalls of the second nanostructures 54 during subsequent oxide etching processes to reduce the risk of undesired etching. The oxide etching processes include processes to remove the sacrificial material 72 as described below in FIGS. 14A and 14B. The second semiconductor material layer 92B may include lateral portions 92B' that results from applying the doping process to the undoped or lightly doped first semiconductor material layer 92A. In embodiments in which the epitaxial source/drain regions 92 comprise four semiconductor material layers, the first semiconductor material layer 92A may be deposited, the second semiconductor material layer 92B may be formed by doping the first semiconductor material layer 92A with a suitable dopant and/or depositing the second semiconductor material layer 92B over the first semiconductor material layer 92A, the third semiconductor material layer 92C may be deposited over the second semiconductor material layer 92B, and the fourth semiconductor material layer 92D may be deposited over the third semiconductor material layer 92C. Other source/drain configurations are also possible in other embodiments.

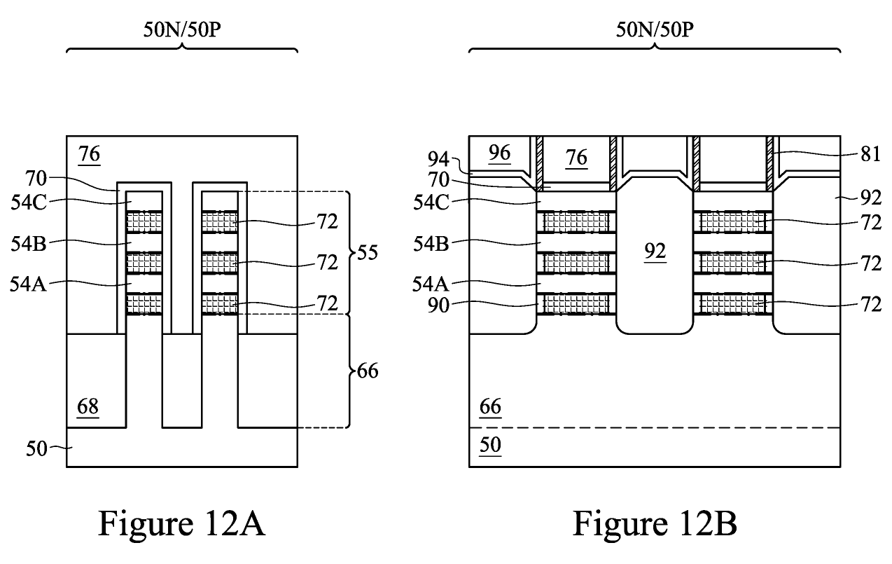

In FIGS. 12A and 12B, a first interlayer dielectric (ILD) 96 is deposited over the structure illustrated in FIGS. 11A and 11B, respectively. The first ILD 96 may be formed of a dielectric material, and may be deposited by any suitable method, such as CVD, plasma-enhanced CVD (PECVD), or FCVD. Dielectric materials may include silicon oxide, phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 94 is disposed between the first ILD 96 and the epitaxial source/drain regions 92, the masks 78, and the gate spacers 81. The CESL 94 may comprise a dielectric material, such as, silicon nitride, silicon oxide, silicon oxynitride, or the like, having a different etch rate than the material of the overlying first ILD 96.

After the first ILD 96 is deposited, a planarization process, such as a CMP, may be performed to level the top surface of the first ILD 96 with the top surfaces of the dummy gates 76 (as shown) or the masks 78. The planarization process may also remove the masks 78 on the dummy gates 76, and portions of the gate spacers 81 along sidewalls of the masks 78. After the planarization process, top surfaces of the dummy gates 76, the gate spacers 81, and the first ILD 96 are level within process variations. Accordingly, the top surfaces of the dummy gates 76 are exposed through the first ILD 96. In some embodiments, the masks 78 may remain, in which case the planarization process levels the top surface of the first ILD 96 with top surface of the masks 78 and the gate spacers 81.

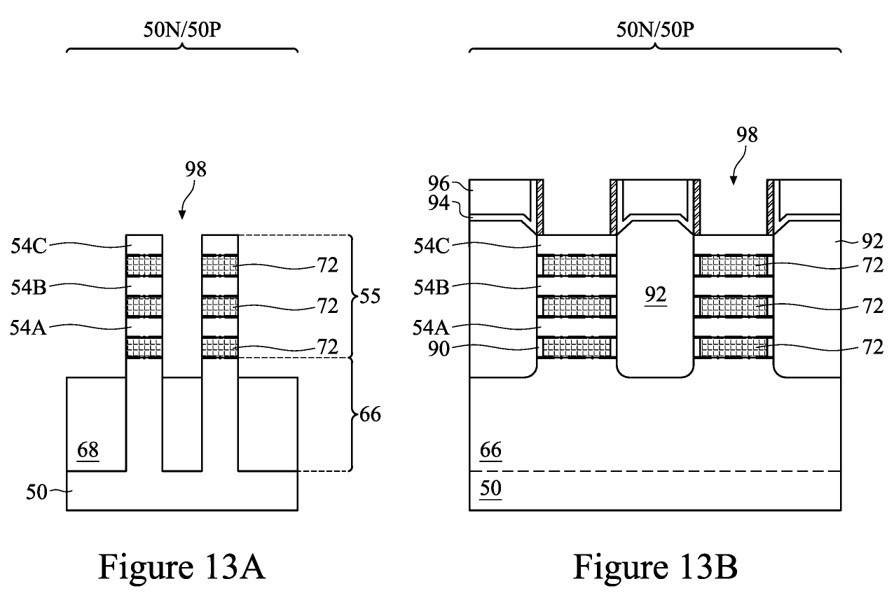

In FIGS. 13A and 13B, the dummy gates 76 are removed in one or more etching steps, so that second recesses 98 are formed. Portions of the dummy gate dielectrics 70 in the second recesses 98 may also be removed. In some embodiments, the dummy gates 76 and the dummy gate dielectrics 70 are removed by an anisotropic dry etch process. For example, the etching process may include a dry etch process using reaction gas(es) that selectively etch the dummy gates 76 at a faster rate than the first ILD 96, or the gate spacers 81. Each second recess 98 exposes and/or overlies portions of nanostructures 55, which act as channel regions in subsequently completed nano-FETs. Portions of the nanostructures 55 which act as the channel regions are disposed between neighboring pairs of the epitaxial source/drain regions 92. During the removal, the dummy gate dielectrics 70 may be used as etch stop layers when the dummy gates 76 are etched. The dummy gate dielectrics 70 may then be removed after the removal of the dummy gates 76.

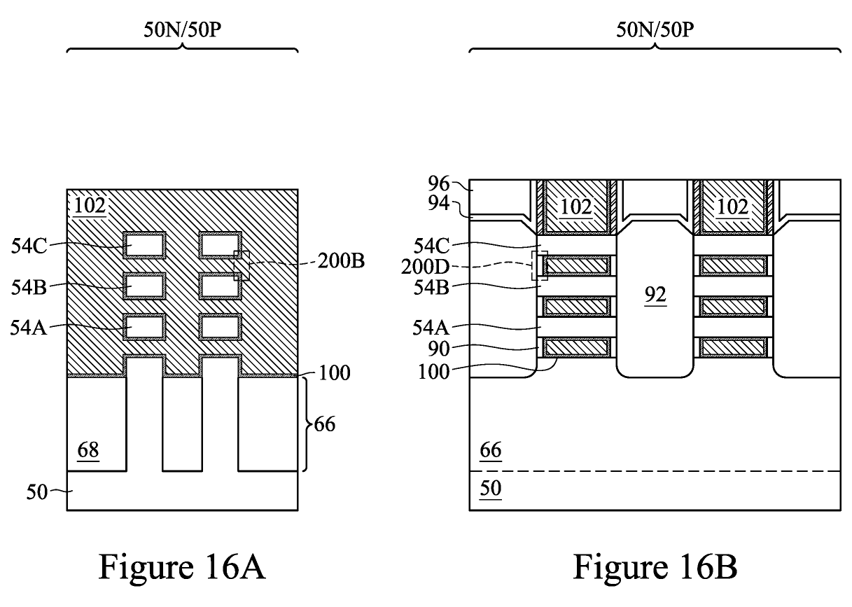

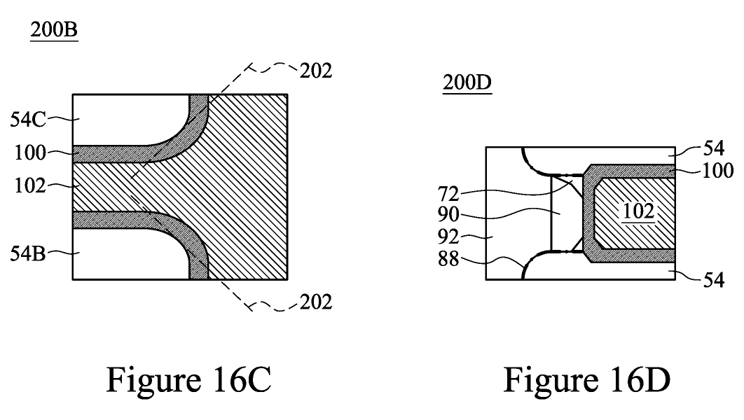

In FIGS. 14A and 14B, the sacrificial material 72 is removed, extending the second recesses 98. Removing the sacrificial material 72 may include performing an isotropic etching process such as wet etching or the like using etchants which are selective to the materials of the sacrificial material 72, while the second nanostructures 54 remain relatively unetched as compared to the sacrificial material 72. The sacrificial material 72 may be completely removed, or a residue of the sacrificial material 72 may remain on sidewalls of the inner spacers in the second recesses 98 (see e.g., FIG. 16D). Removing the sacrificial material 72 may expose the impurities 88 at surfaces of the second nanostructures 54 in the second recesses 98.

In some embodiments, the STI regions 68 may be etched while removing the sacrificial material 72, but the total amount of loss in the STI regions 68 may be reduced by controlling etching parameters (e.g., timing) while removing the sacrificial material 72. In other embodiments, the STI regions 68 may include a hard mask (not separately illustrated) at a top surface to protect the underlying STI regions 68 from etching while patterning and removing the sacrificial material 72. In such embodiments, the hard mask may comprise, for example, a nitride.

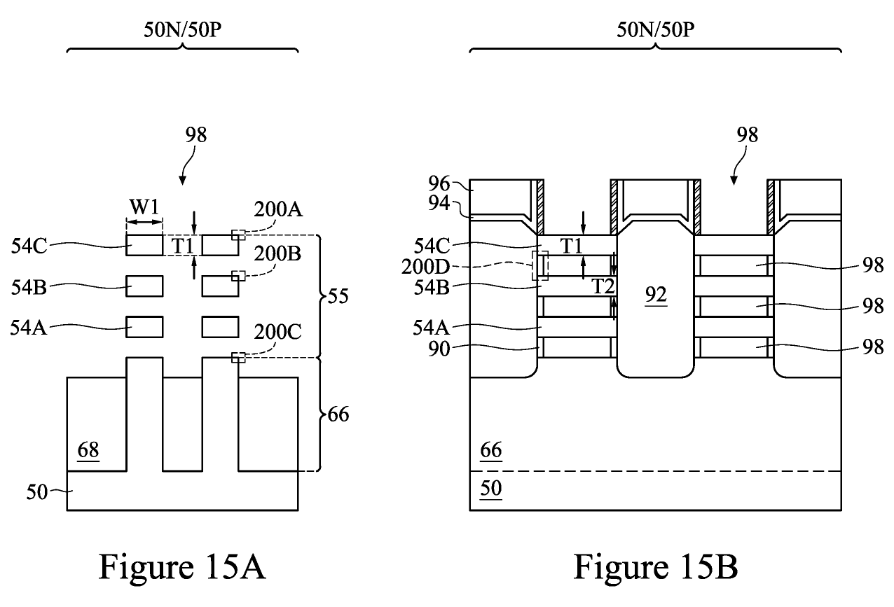

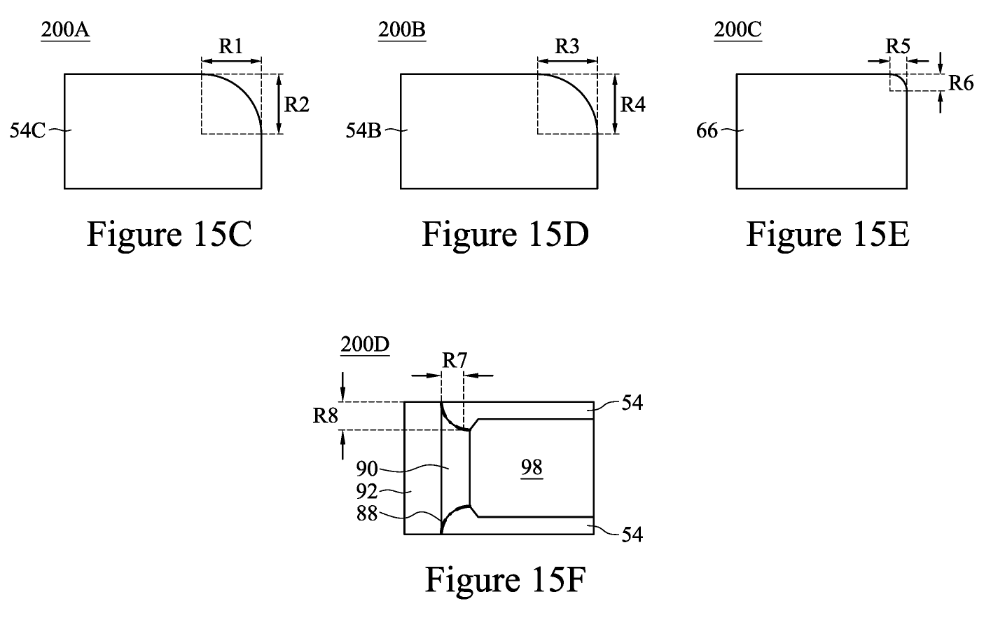

In FIGS. 15A-15F, a trimming process is performed on the second nanostructures 54, which removes the impurities 88 from exposed surfaces of the second nanostructures 54, such as surfaces of the second nanostructures 54 in the second recesses 98. Removing the impurities 88 may provide improved device performance in the resulting nano-FETs, such as increased carrier mobility, reduced channel resistance, or the like. In some embodiments, the inner spacers 90 and/or residue from the sacrificial material 72 mask certain regions of the second nanostructures 54 during the trimming process. As such, a small portion of the impurities 88 may remain at interfaces between the inner spacers 90 and the second nanostructures 54 (see e.g., FIG. 15F and 16D). These relatively small areas of remaining impurities 88 may not significantly degrade device performance.

The trimming process may be accomplished through a wet etching process. For example, a wet etching process with an etchant solution comprising ammonia, hydrogen peroxide (H₂O₂), or the like in water (H₂O) may be used to trim the second nanostructures 54. The duration of the wet etching process may range from 60 seconds to 400 seconds. It has been observed that an etching time of less than 60 seconds, risks impurities 88 on the nanostructures 54. Conversely, extending the etching time beyond 400 seconds may negatively impact the size and/or profile of the resulting nanostructures 54. In one embodiment, the wet etching temperature is maintained between 30° C and 60° C. In some alternative embodiments, a narrower temperature range of 40° C to 50° C may be employed. It has been observed that if the etching temperature falls below 30° C, the etching rate becomes undesirably low. On the other hand, temperatures exceeding 60° C present challenges in maintaining uniform temperature across the device (e.g., the wafer) being processed. This temperature non-uniformity between the wafer center and edge can lead to significant differences in the profile of the second nanostructures 54, negatively affecting device consistency and quality. These parameters can be adjusted based on specific requirements of the trimming process, the materials involved, and the desired outcomes in terms of size, profile, and uniformity of the second nanostructures 54.

After the trimming process, the second nanostructures 54 and the fins 66 may have a trimmed profile. The trimming process may increase a curvature of exposed, corner regions of the second nanostructures 54 and/or the fins 66. Increasing the curvature of corner regions may increase a gap fill window for a subsequently formed gate stack (see FIGS. 16A-16D), thereby reducing gaps in the gate stack and reducing high-k damage (e.g., damage over time due to corona discharge). After the trimming process, the specific geometries of the corner regions of the second nanostructures 54 and the fins 66 may vary depending on the specific location of corners of the second nanostructures 54 and the fins 66. Generally, etching bias is relatively minimal across the device. For example, in some embodiments, a loading effect between isolated and dense pattern regions across the device may be relatively minimal.

FIGS. 15C, 15D, and 15E illustrate detailed views of corner regions 200A, 200B, and 200C, respectively, of the second nanostructures 54 (see also FIG. 15A). Each of the corner regions 200A, 200B, and 200C are taken from a cross-sectional view along cross-section A-A' (see FIG. 1), which extends along a longitudinal axis of a subsequently formed gate electrode 102 (see FIGS. 16A-16D) and in a direction perpendicular to the direction of current flow between the epitaxial source/drain regions 92 of a nano-FET. Corner region 200A illustrates top corners of a topmost nanostructure 54C of the stack of nanostructures along the cross-section A-A’. The corner regions 200A have horizontal radii R1 and vertical radii R2, which are each in a range of 1 nm to 4.5 nm. The horizontal radii R1 may or may not be equal to the vertical radii R2.

Corner regions 200B are representative of remaining corners other than the top corners of the topmost nanostructures 54 along the cross-section A-A'. For example, the corner regions 200B are representative of corner profiles of bottom corners of the top nanostructures 54C and top and bottom corners of the second nanostructures 54B and 54A along the cross-section A-A'. The corner regions 200B have horizontal radii R3 and vertical radii R4, which are each in a range of 0.9 nm to 2 nm. The horizontal radii R3 may or may not be equal to the vertical radii R4. It has been observed that when the corner regions 200B have radii in the above ranges, the gap fill window for subsequently formed gate stacks can be sufficiently increased to reduce gaps in the gate stack and reduce high-k dielectric damage. In some embodiments, the corner regions 200A may be rounder and have a greater curvature than the corner regions 200B due to the corner regions 200A being exposed to additional processing (e.g., removal of the dummy gates 76 and the dummy gate dielectrics 70). For example, the horizontal radii R1 and the vertical radii R2 of the corner regions 200A may be greater than the horizontal radii R3 and the vertical radii R4, respectively, of the corner regions 200B.

Corner regions 200C are representative of corners of the fins 66 along the cross-section A-A'. The corner regions 200C have horizontal radii R5 and vertical radii R6, which are each in a range of 0.9 nm to 3 nm. The horizontal radii R5 may or may not be equal to the vertical radii R6. In some embodiments, the corner regions 200A may be rounder and have a greater curvature than the corner regions 200C due to the corner regions 200A being exposed to additional processing (e.g., removal of the dummy gates 76 and the dummy gate dielectrics 70). For example, the horizontal radii R1 and the vertical radii R2 of the corner regions 200A may be greater than the horizontal radii R5 and the vertical radii R6, respectively, of the corner regions 200C. Still further, the horizontal radii R3 and the vertical radii R4 of the corner regions 200B may or may not be equal to the horizontal radii R5 and the vertical radii R6, respectively, of the corner regions 200C.

The profiles and dimensions and the second nanostructures 54 may also vary depending on the cross-section. Specifically, the inner spacers 90 and the source/drain regions 92 may cover corner regions of the second nanostructures in the cross-section B-B' (see FIG. 1). As such, corner regions in the cross-sections B-B' and may have a lower degree of curvature and be less round than corner regions the cross-section A-A'. For example, FIG. 15F illustrates a detailed view of corner regions 200D (see also FIG. 15B). The corner regions 200D are disposed in cross-section B-B', which is perpendicular to cross-section A-A’ and is parallel to a longitudinal axis of a fin 66 of the nano-FET. The corner regions 200D have horizontal radii R7 and vertical radii R8, which are each in a range of 0.2 nm to 1.2 nm. The horizontal radii R7 may or may not be equal to the vertical radii R8. The corner regions 200D may be less round than the corner regions 200A, 200B, and 200C. For example, the horizontal radii R7 and the vertical radii R8 of the corner regions 200D may each be less than respective horizontal radii R1, R3, R5 and vertical radii R2, R4, R6 of the corner regions 200A, 200B, and 200C. Still further, the corner regions 200D may be thinner than trimmed areas of the second nanostructures 54. For example, the second nanostructures 54 may have a width W1 in a range of 5nm to 100 nm, and a thickness T1 in a range of 4 nm to 6.5 nm in the cross-section A-A'. However, in the cross-section B-B', portions of the second nanostructures 54 that are masked (e.g., by the inner spacers 90) may have a thickness T2 that is greater than the thickness T1 while portions of the second nanostructures 54 that are exposed by the recess 98 have the thickness T1.

In FIGS. 16A-16D, gate dielectric layers 100 and gate electrodes 102 are formed for replacement gates. The gate dielectric layers 100 are deposited conformally in the second recesses 98. The gate dielectric layers 100 may be formed on top surfaces and sidewalls of the substrate 50 and on top surfaces, sidewalls, and bottom surfaces of the second nanostructures 54. The gate dielectric layers 100 may also be deposited on top surfaces of the first ILD 96, the CESL 94, the gate spacers 81, and the STI regions 68.

In accordance with some embodiments, the gate dielectric layers 100 comprise one or more dielectric layers, such as an oxide, a metal oxide, the like, or combinations thereof. For example, in some embodiments, the gate dielectrics may comprise a silicon oxide layer and a metal oxide layer over the silicon oxide layer. In some embodiments, the gate dielectric layers 100 include a high-k dielectric material, and in these embodiments, the gate dielectric layers 100 may have a k value greater than about 7.0, and may include a metal oxide or a silicate of hafnium, aluminum, zirconium, lanthanum, manganese, barium, titanium, lead, and combinations thereof. The structure of the gate dielectric layers 100 may be the same or different in the n-type region 50N and the p-type region 50P. The formation methods of the gate dielectric layers 100 may include molecular-beam deposition (MBD), ALD, PECVD, and the like.

The gate electrodes 102 are deposited over the gate dielectric layers 100, respectively, and fill the remaining portions of the second recesses 98. The gate electrodes 102 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 102 are illustrated in FIGS. 16A-16D, the gate electrodes 102 may comprise any number of liner layers, any number of work function tuning layers, and a fill material. Any combination of the layers which make up the gate electrodes 102 may be deposited in the n-type region 50N and the p-type region 50P between adjacent ones of the second nanostructures 54 and between the second nanostructure 54A and the substrate 50.

The formation of the gate dielectric layers 100 in the n-type region 50N and the p-type region 50P may occur simultaneously such that the gate dielectric layers 100 in each region are formed from the same materials, and the formation of the gate electrodes 102 may occur simultaneously such that the gate electrodes 102 in each region are formed from the same materials. In some embodiments, the gate dielectric layers 100 in each region may be formed by distinct processes, such that the gate dielectric layers 100 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes.

After the filling of the second recesses 98, a planarization process, such as a CMP, may be performed to remove the excess portions of the gate dielectric layers 100 and the material of the gate electrodes 102, which excess portions are over the top surface of the first ILD 96. The remaining portions of material of the gate electrodes 102 and the gate dielectric layers 100 thus form replacement gate structures of the resulting nano-FETs. The gate electrodes 102 and the gate dielectric layers 100 may be collectively referred to as “gate structures.”

FIGS. 16C illustrates a detailed view of the corner regions 200B (see FIGS. 15A and 16A). As can be see, the rounded corners of the second nanostructures 54 provide a v-shaped opening for deposition of the gate dielectric layers 100 and the gate electrodes 102 between the second nanostructures 54. For example, a vertical distance between lines 202 that are tangent to adjacent corners of the second nanostructures 54 may increase in a direction away from the second nanostructures 54. As a result, the deposition window for depositing the gate dielectric layers 100 and the gate electrodes 102 is widened, and gap filling can be improved. For example, it has been observed that when corner regions 200B have radii in a range of 0.9 nm to 2 nm, improved coverage and reduced gaps in the gate dielectric layers 100 and the gate electrodes 102 can be achieved between the second nanostructures 54. Improved coverage has the added benefit of reducing damage to high-k layers of the gate dielectric layers 100 over time due to corona discharge from the gate electrodes 102.

FIG. 16D illustrates a detailed view of the corner regions 200D (see FIG. 16B), including the epitaxial source/drain regions 92, the gate dielectric layers 100, the gate electrodes 102, the second nanostructures 54, and the inner spacers 90. In some embodiments, as illustrated by FIG. 16D, a residue of the sacrificial material 72 may remain on the inner spacers 90, such as between the inner spacers 90 and the gate dielectric layers 100/gate electrodes 102. For example, the sacrificial material 72 may not be fully removed, and the gate dielectric layers 100 may be formed on the remaining sacrificial material 72. Because the sacrificial material 72 is an insulating material (e.g., silicon oxide), the remaining residue may not significantly impact the electrical performance of the resulting device.

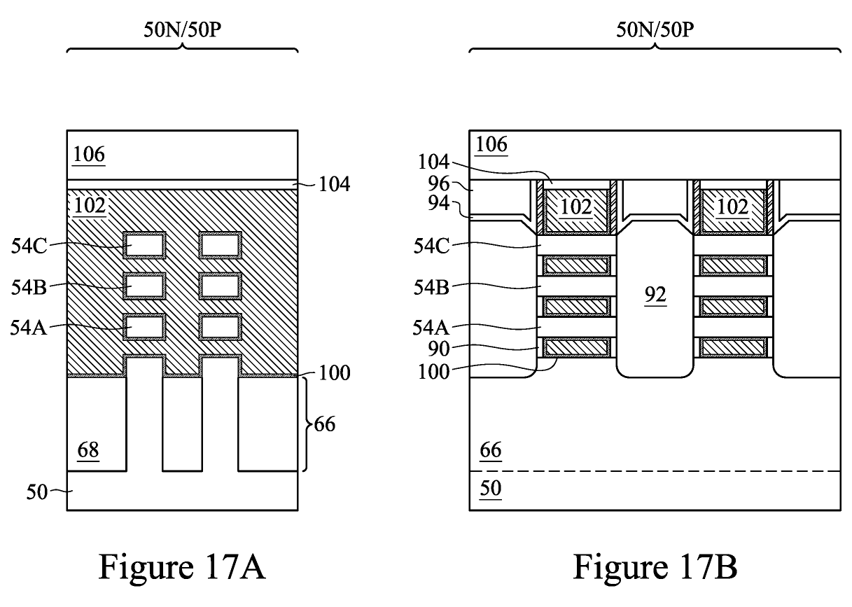

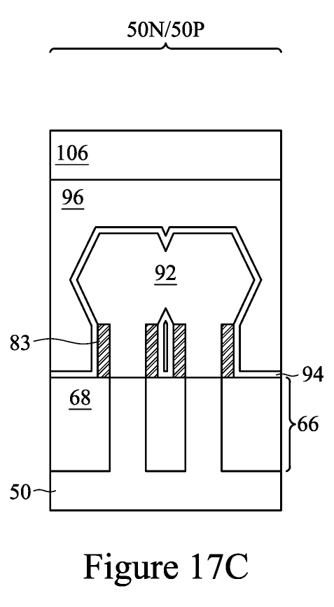

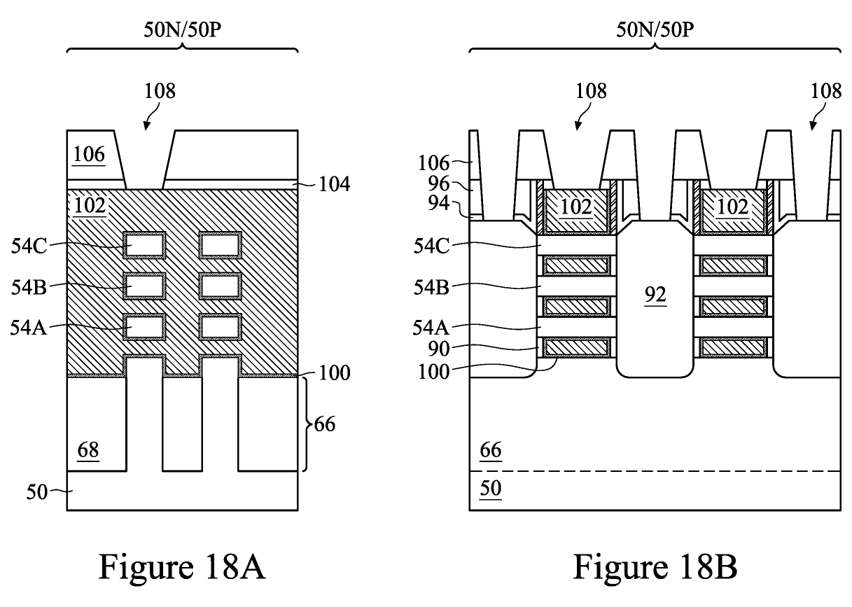

In FIGS. 17A-17C, the gate structure (including the gate dielectric layers 100 and the corresponding overlying gate electrodes 102) is recessed, so that a recess is formed directly over the gate structure and between opposing portions of gate spacers 81. A gate mask 104 comprising one or more layers of dielectric material, such as silicon nitride, silicon oxynitride, or the like, is filled in the recess, followed by a planarization process to remove excess portions of the dielectric material extending over the first ILD 96. Subsequently formed gate contacts (such as the gate contacts 114, discussed below with respect to FIGS. 18A-18B) penetrate through the gate mask 104 to contact the top surface of the recessed gate electrodes 102.

As further illustrated by FIGS. 18A-18B, a second ILD 106 is deposited over the first ILD 96 and over the gate mask 104. In some embodiments, the second ILD 106 is a flowable film formed by FCVD. In some embodiments, the second ILD 106 is formed of a dielectric material such as PSG, BSG, BPSG, USG, or the like, and may be deposited by any suitable method, such as CVD, PECVD, or the like.

In FIGS. 18A-18B, the second ILD 106, the first ILD 96, the CESL 94, and the gate masks 104 are etched to form third recesses 108 exposing surfaces of the epitaxial source/drain regions 92 and/or the gate structure. The third recesses 108 may be formed by etching using an anisotropic etching process, such as RIE, NBE, or the like. In some embodiments, the third recesses 108 may be etched through the second ILD 106 and the first ILD 96 using a first etching process; may be etched through the gate masks 104 using a second etching process; and may then be etched through the CESL 94 using a third etching process. A mask, such as a photoresist, may be formed and patterned over the second ILD 106 to mask portions of the second ILD 106 from the first etching process and the second etching process. In some embodiments, the etching process may over-etch, and therefore, the third recesses 108 extend into the epitaxial source/drain regions 92 and/or the gate structure, and a bottom of the third recesses 108 may be level with (e.g., at a same level, or having a same distance from the substrate), or lower than (e.g., closer to the substrate) the epitaxial source/drain regions 92 and/or the gate structure. Although FIG. 18B illustrate the third recesses 108 as exposing the epitaxial source/drain regions 92 and the gate structure in a same cross section, in various embodiments, the epitaxial source/drain regions 92 and the gate structure may be exposed in different cross-sections, thereby reducing the risk of shorting subsequently formed contacts.

After the third recesses 108 are formed, silicide regions 110 are formed over the epitaxial source/drain regions 92. In some embodiments, the silicide regions 110 are formed by first depositing a metal (not shown) capable of reacting with the semiconductor materials of the underlying epitaxial source/drain regions 92 (e.g., silicon, silicon germanium, germanium) to form silicide or germanide regions. For example, metals such as nickel, cobalt, titanium, tantalum, platinum, tungsten, other noble metals, other refractory metals, rare earth metals or their alloys, may be used. The metal may be deposited over the exposed portions of the epitaxial source/drain regions 92. A thermal annealing process may then be utilized to form the silicide regions 110. The un-reacted portions of the deposited metal are then removed, e.g., by an etching process. Although silicide regions 110 are referred to as silicide regions, silicide regions 110 may also be germanide regions, or silicon germanide regions (e.g., regions comprising silicide and germanide). In an embodiment, the silicide region 110 comprises TiSi, and has a thickness in a range between about 2 nm and about 10 nm.

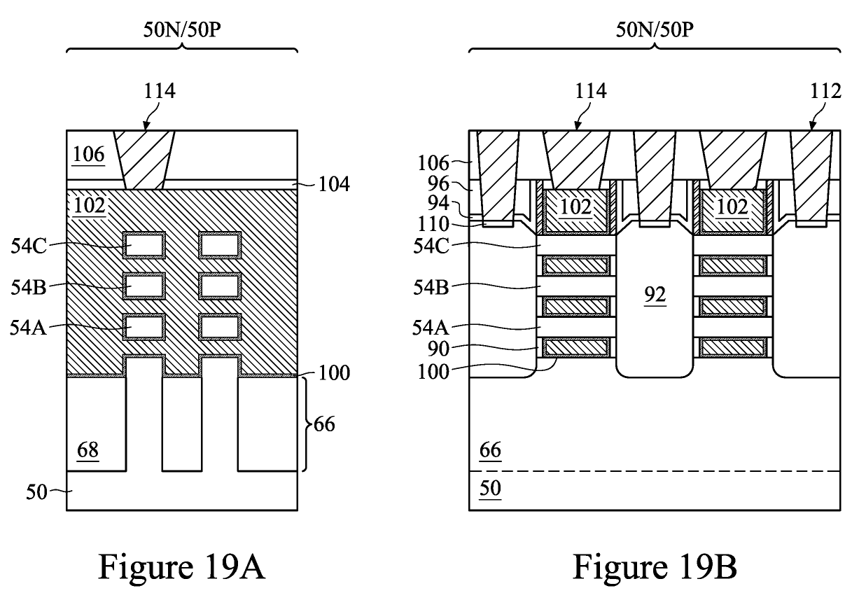

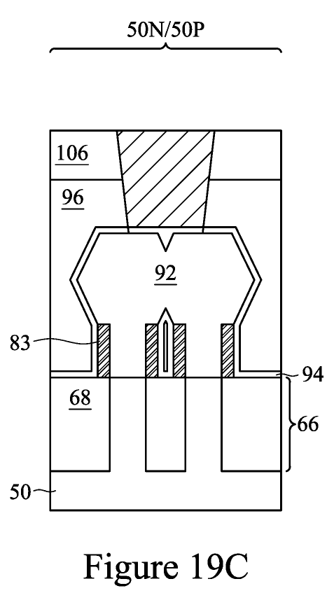

Next, in FIGS. 19A-19C, contacts 112 and 114 (may also be referred to as contact plugs) are formed in the third recesses 108. The contacts 112 and 114 may each comprise one or more layers, such as barrier layers, diffusion layers, and fill materials. For example, in some embodiments, the contacts 112 and 114 each include a barrier layer and a conductive material, and are electrically coupled to the underlying conductive feature (e.g., gate structure 102 and/or silicide region 110 in the illustrated embodiment). The contacts 114 are electrically coupled to the gate structure 102 and may be referred to as gate contacts, and the contacts 112 are electrically coupled to the silicide regions 110 and may be referred to as source/drain contacts. The barrier layer may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 106.

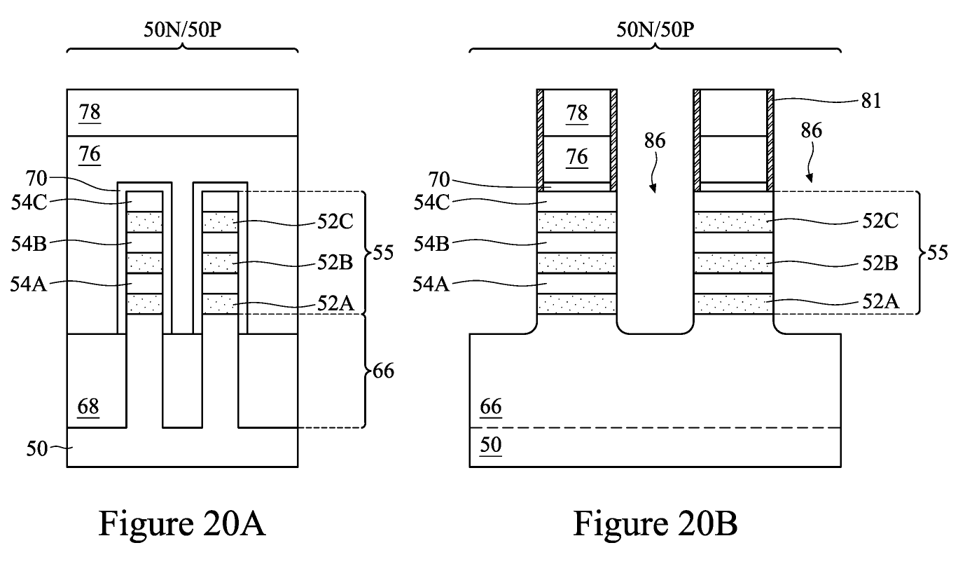

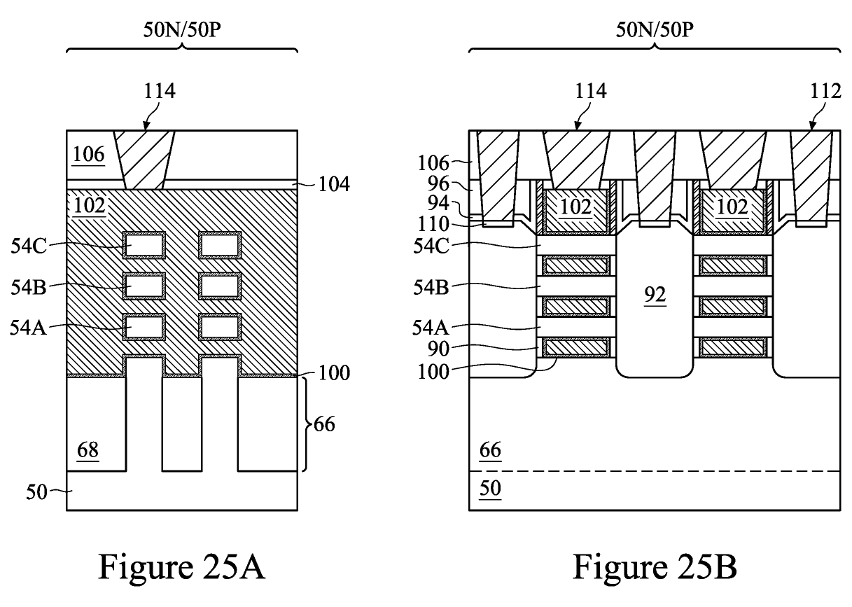

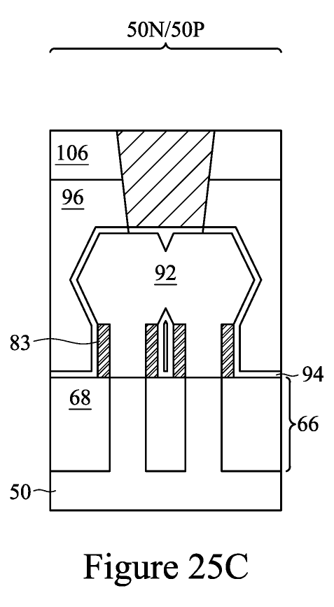

FIGS. 20A through 25C are cross-sectional views of intermediate stages in the manufacturing of nano-FETs, in accordance with some embodiments. FIGS. 20A, 21A, 22A, 22F, 22G, 22H, 23A, 24A, and 25A illustrate reference cross-section A-A’ illustrated in FIG. 1. FIGS. 20B, 21B, 22B, 22C, 22D, 22E, 23B, 24B, and 25B illustrate reference cross-section B-B’ illustrated in FIG. 1. FIG. 25C illustrates reference cross-section C-C’ illustrated in FIG. 1. Referring first to FIGS. 20A and 20B, a device at a same stage of processing as described above in FIGS. 7A-7C is illustrated where like reference numerals indicate like elements formed by like processes. FIGS. 20A and 20B illustrate a manufacturing stage after forming the recesses 86 that expose sidewalls of the first nanostructures 52 and the second nanostructures 54. In FIGS. 20A and 20B, the first nanostructures 52 are not yet replaced by any sacrificial material.

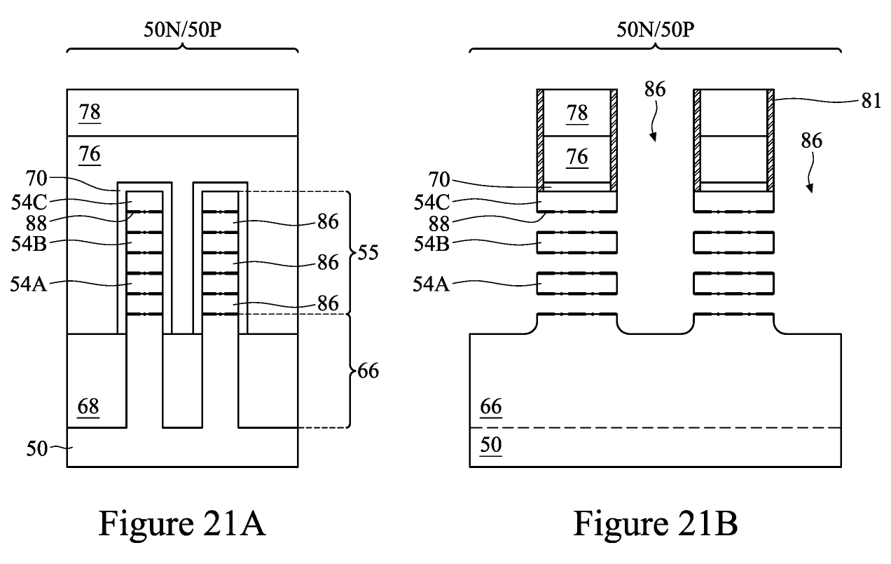

In FIGS. 21A and 21B, the first nanostructures 52 are removed, extending the first recesses 86 between the second nanostructures 54. The first nanostructures 52 may be removed using a suitable process, such as those described above in FIGS. 8A and 8B. The removal of the first nanostructures 52 results in impurities 88 being left on exposed surfaces of the second nanostructures 54. Specifically, the impurities may be disposed on surfaces of the second nanostructures 54 in the first recesses 86.

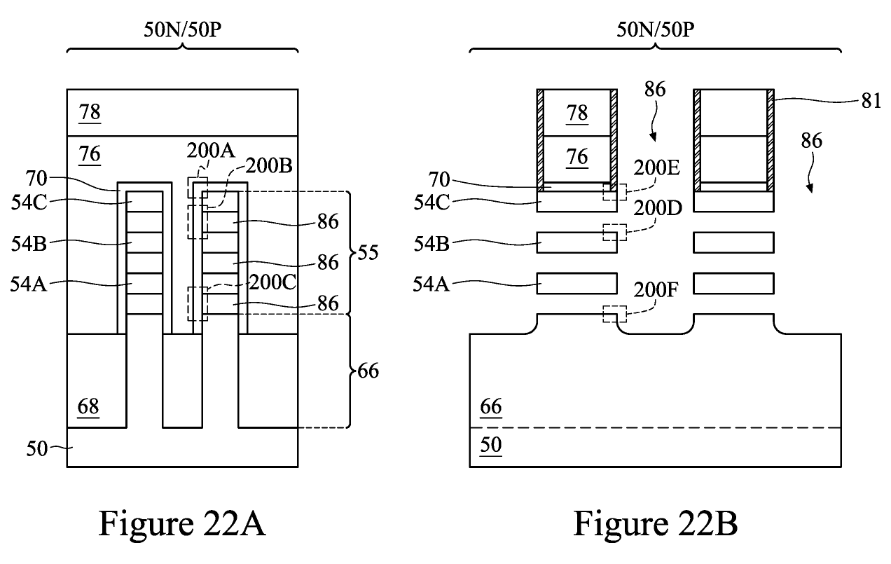

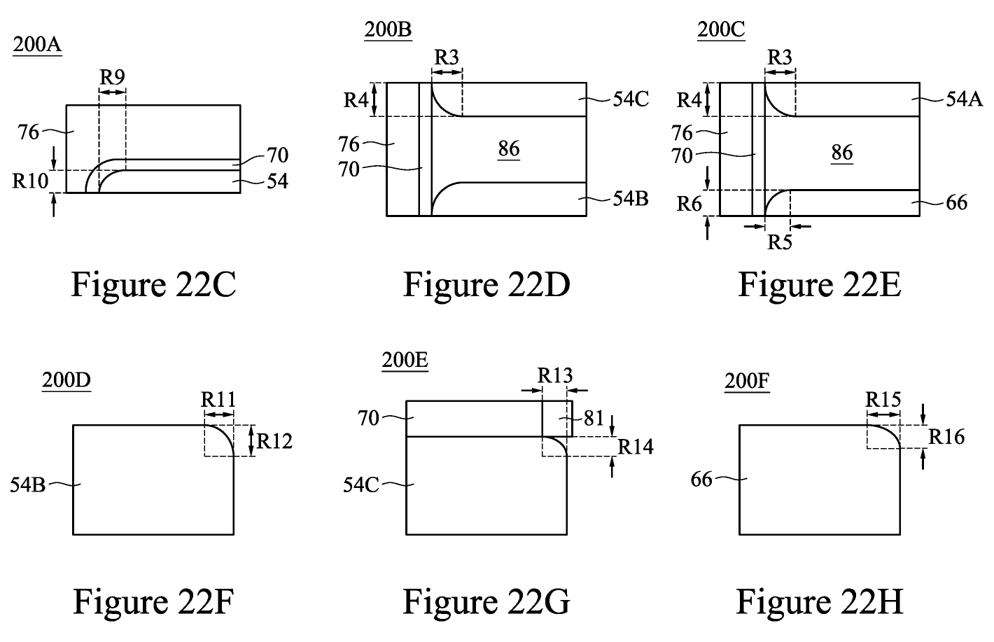

In FIGS. 22A-22H, a trimming process is performed to remove the impurities 88. Unlike the embodiments described above in FIGS. 2-19C, the embodiments of FIGS. 20A-25C describe a process where the second nanostructures 54 are trimmed prior to forming the sacrificial material 72, the inner spacers 90, and the source/drain regions 92. The trimming process may be performed using a wet etching process as described above in FIGS. 15A through 15F. For example, the trimming process may be accomplished through a wet etching process with an etchant solution comprising ammonia, hydrogen peroxide (H₂O₂), or the like in water. The duration of the wet etching process may range from 60 seconds to 400 seconds. It has been observed that an etching time of less than 60 seconds, risks impurities 88 on the nanostructures 54. Conversely, extending the etching time beyond 400 seconds may negatively impact the size and/or profile of the resulting nanostructures 54. In one embodiment, the wet etching temperature is maintained between 30° C and 60° C or between 40° C and 50° C. It has been observed that if the etching temperature falls below 30° C, the etching rate becomes undesirably low. On the other hand, temperatures exceeding 60° C present challenges in maintaining uniform temperature across the device (e.g., the wafer) being processed. Removing the impurities 88 may provide improved device performance in the resulting nano-FETs, such as increased carrier mobility, reduced channel resistance, or the like.

After the trimming process, the second nanostructures 54 and the fins 66 may have a trimmed profile. The trimming process may increase a curvature of exposed, corner regions of the second nanostructures 54 and/or the fins 66. Increasing the curvature of corner regions may increase a gap fill window for a subsequently formed gate stack (see FIGS. 25A-25C), thereby reducing gaps in the gate stack and reducing high-k damage (e.g., damage over time due to corona discharge). After the trimming process, the specific geometries of the corner regions of the second nanostructures 54 and the fins 66 may vary depending on the specific location of corners of the second nanostructures 54 and the fins 66.

FIGS. 22C, 22D, and 22E illustrate detailed views of corner regions 200A, 200B, and 200C, respectively (see also FIG. 22A). Each of the corner regions 200A, 200B, and 200C are taken from a cross-sectional view along line A-A' (see FIG. 1), which extends along a longitudinal axis of a subsequently formed gate electrode 102 (see FIGS. 25A-25C) and in a direction perpendicular to the direction of current flow between the epitaxial source/drain regions 92 of a nano-FET. Corner region 200A illustrates top corners of a topmost nanostructure 54C of the stack of nanostructures along the cross-section A-A’. Because the dummy gates 76 mask the corner regions 200A, the curvature of the corner regions 200A is relatively low. For example, the corner regions 200A have horizontal radii R9 and vertical radii R10, which are each in a range of 0.2 nm to 1.2 nm. The horizontal radii R9 may or may not be equal to the vertical radii R10.

Corner regions 200B are representative of remaining corners other than the top corners of the topmost nanostructures 54 along the cross-section A-A'. For example, the corner regions 200B are representative of corner profiles of bottom corners of the top nanostructures 54C and top and bottom corners of the second nanostructures 54B and 54A along the cross-section A-A'. The corner regions 200B have horizontal radii R3 and vertical radii R4, which are each in a range of 0.9 nm to 2 nm. The horizontal radii R3 may or may not be equal to the vertical radii R4. In some embodiments, the corner regions 200B may have radii R3 and R4 in the range of 0.9 nm and 2 nm following additional processing (e.g., the removal of the dummy gates 76). It has been observed that when the corner regions 200B have radii in the above ranges, the gap fill window for subsequently formed gate stacks can be sufficiently increased to reduce gaps in the gate stack and reduce high-k dielectric damage. In some embodiments, the corner regions 200B may be rounder and have a greater curvature than the corner regions 200A due to the corner regions 200A being masked by the dummy gates 76 during the trimming process. For example, the horizontal radii R9 and the vertical radii R10 of the corner regions 200A may be less than the horizontal radii R3 and the vertical radii R4, respectively, of the corner regions 200B.

Corner regions 200C are representative of corners of the fins 66 along the cross-section A-A'. The corner regions 200C have horizontal radii R5 and vertical radii R6, which are each in a range of 0.9 nm to 3 nm. The horizontal radii R5 may or may not be equal to the vertical radii R6. In some embodiments, the corner regions 200C may be rounder and have a greater curvature than the corner regions 200A due to the corner regions 200A being masked by the dummy gates 76. For example, the horizontal radii R9 and the vertical radii R10 of the corner regions 200A may be less than the horizontal radii R5 and the vertical radii R6, respectively, of the corner regions 200C. Still further, the horizontal radii R3 and the vertical radii R4 of the corner regions 200B may or may not be equal to the horizontal radii R5 and the vertical radii R6, respectively, of the corner regions 200C.

The profiles and dimensions and the second nanostructures 54 may also vary depending on the cross-section. However, because the trimming process is performed prior to forming the inner spacers 90 or the source/drain regions 92, curvatures of corner regions in the different cross-sections are generally more uniform than the embodiments of FIGS. 2 through 19C. Specifically, the inner spacers 90 and the source/drain regions 92 are not yet formed and do not mask corner regions of the second nanostructures in the cross-section B-B' (see FIG. 1). As such, corner regions in the cross-sections B-B' and may have a similar degree of curvature as the corner regions 200B and 200C in the cross-section A-A'.

For example, FIGS. 22C, 22D, and 22E illustrate detailed views of corner regions 200D, 200E, and 200F, respectively (see also FIG. 22B). Each of the corner regions 200D, 200E, and 200F are taken from a cross-sectional view along cross-section B-B' (see FIG. 1), which is perpendicular to cross-section A-A’ and is parallel to a longitudinal axis of a fin 66 of the nano-FET. The corner regions 200E represent top corners of a topmost second nanostructure 54 (e.g., the nanostructures 54C). The corner regions 200D are representative of remaining corners other than the top corners of the topmost nanostructures 54 along the cross-section B-B'. For example, the corner regions 200B are representative of corner profiles of bottom corners of the top nanostructures 54C and top and bottom corners of the second nanostructures 54B and 54A along the cross-section B-B'. The corner regions 200F represent corners of the fins 66 along the cross-section B-B'. As illustrated in FIGS. 22F, the corner regions 200D have horizontal radii R11 and vertical radii R12, which may be substantially similar to the horizontal radii R3 and the vertical radii R4 of the corner regions 200B. For example, each of the horizontal radii R11 and the vertical radii R12 may be in the range of 0.9 nm to 2 nm. As illustrated in FIGS. 22G, the corner regions 200E have horizontal radii R13 and vertical radii R14, which may be substantially similar to the horizontal radii R9 and the vertical radii R10 of the corner regions 200A. As illustrated in FIGS. 22H, the corner regions 200 have horizontal radii R15 and vertical radii R16, which may be substantially similar to the horizontal radii R5 and the vertical radii R6 of the corner regions 200C.

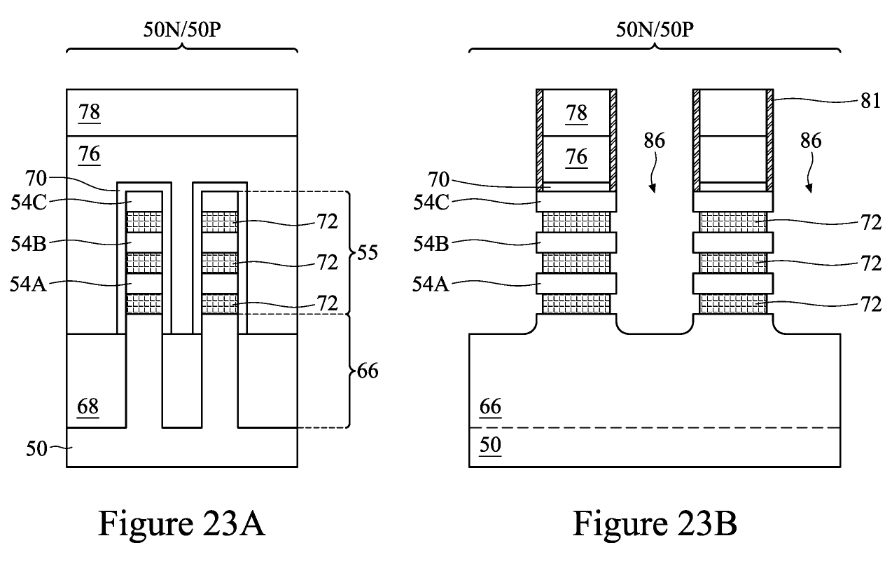

In FIGS. 23A and 23B, a sacrificial material 72 is formed between the second nanostructures 54. The sacrificial material 72 may be formed using a similar process as described above in FIGS. 8A-9B. For example, the sacrificial material 72 are be formed by depositing a sacrificial material layer (e.g., an oxide, or the like) and then etching the sacrificial material layer. Because the second nanostructures 54 are trimmed prior to forming the sacrificial material 72, the impurities 88 are not disposed at an interface between the sacrificial material 72 and the second nanostructures 54.

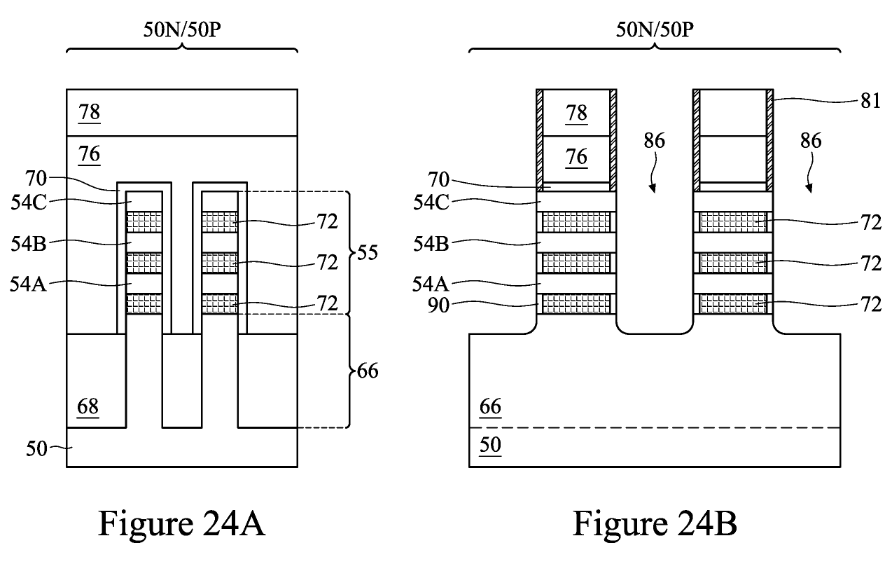

Next, in FIGS. 24A and 24B, inner spacers 90 are formed along sidewalls of the sacrificial material 72, between the second nanostructures 54. The inner spacers 90 may be formed using a similar process as described above in FIGS. 8A-9B. For example, the sacrificial material 72 are be formed by depositing a sacrificial material layer (e.g., an oxide, or the like) and then etching the sacrificial material layer. Because the second nanostructures 54 are trimmed prior to forming the sacrificial material 72, the impurities 88 are not disposed at an interface between the sacrificial material 72 and the second nanostructures 54.

FIGS. 25A-25C illustrates the completed device after additional processing similar to that described above in FIGS. 11A-14B and 16A-19C is performed where like reference numerals indicate like elements formed by like processes. In this embodiment, at corners of the nanostructures 54 may have the profiles described above in FIGS. 22C-22H. For example, the nanostructures 54 may have corner regions with vertical and horizontal radii in a range of 0.9 nm to 2 nm along both cross-sections A-A' and B-B'. When the corner regions have radii in the above ranges, gate deposition between the second nanostructures 54 may be achieved with improved gap fill, and high-k gate dielectric damage can be reduced.

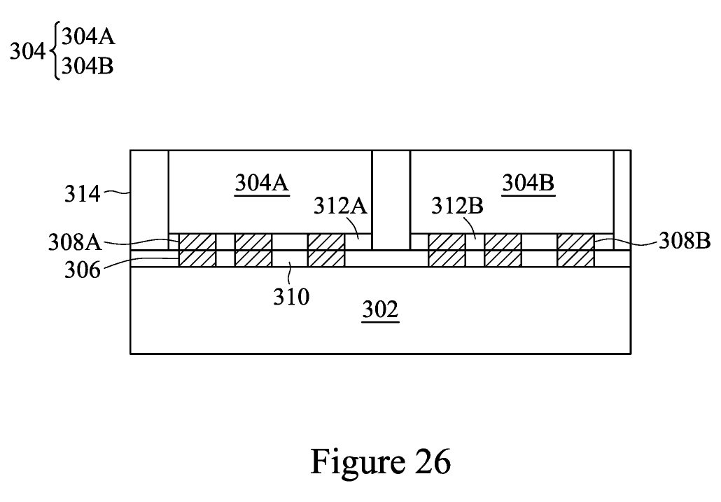

FIG. 26 illustrate a semiconductor package formed by bonding integrated circuit dies 302 and 304 (including integrated circuit dies 304A and 304B) according to some embodiments. Each of the integrated circuit dies 302 and 304 may include active devices that are formed with different processes. For example, the integrated circuit die 304A may include nano-FET devices formed by the process described above in FIGS. 2-19C where the trimming process is performed after removing the sacrificial material 72, and the integrated circuit die 304B may include nano-FET devices formed by the process described above in FIGS. 20A-25C where the trimming process is performed before forming the sacrificial material 72, the inner spacers 90, and the source/drain regions 92. Further, the integrated circuit die 302 may include nano-FET devices where the trimming process is not performed and the sacrificial material 72 is not formed. For example, the nano-FET devices in the integrated circuit die 302 may be formed by directly replacing the first nanostructures 52 with the gate stack 100/102 without trimming the second nanostructures 54. As a result, profiles of nanostructures within each of the integrated circuit dies 302 and 304 may vary due to differences in the device fabrication processes.

The integrated circuit dies 304 and 302 may be directly bonded together with metal-to-metal bonding and dielectric-to-dielectric bonding. For example, contact pads (e.g., copper pads) 306 of the integrated circuit die 302 may be directly bonded to contact pads (e.g., copper pads) 308A of the integrated circuit die 304A and contact pads (e.g., copper pads) 308B of the integrated circuit die 304B without any intervening solder connections. Further, insulating bonding layer 310 of the integrated circuit die 302 may be directly bonded to the insulating bonding layers 312A and 312B of the integrated circuit dies 304A and 304B, respectively. Bonding the insulating bonding layers 310, 312A, and 312B may include planarizing (e.g., CMP) each of the insulating bonding layers 310, 312A, and 312B, and then bonding the layers 310, 312A, and 312B together by direct oxide-to-oxide bonding without any intervening adhesive, for example. A molding compound 314 may then be deposited over the integrated circuit die 302 and around the integrated circuit dies 304A and 304B.

In various embodiments, nano-FET formation involves alternately stacking first and second nanostructures, then replacing the second nanostructures with a gate stack surrounding the first nanostructures. This replacement process may leave impurities on the first nanostructures, and a trimming step is performed to remove these residues and improve device performance. Trimming also rounds the corners of the first nanostructures, typically defining nanostructure corners with vertical and/or horizontal radii between 0.9 nm and 2 nm. These rounded corners increase the deposition window for the gate stack, leading to improved gap fill between nanosheets, reduced gaps in the gate stack, and decreased high-k dielectric damage over time. Overall, these processes result in nano-FETs with enhanced carrier mobility, reduced channel resistance, and reduced high-k damage.

In some embodiments, a method includes removing first nanostructures from a plurality of nanostructures, the plurality of nanostructures comprising the first nanostructures alternatingly stacked with second nanostructures; after removing the first nanostructures, performing a trimming process on the second nanostructures, wherein the trimming process increases a curvature of at least a first corner of the second nanostructures; forming a sacrificial material between the second nanostructures; and replacing the sacrificial material with a gate stack. Optionally, replacing the sacrificial material with the gate stack comprises removing the sacrificial material, and wherein the trimming process is performed after removing the sacrificial material. Optionally, the method further includes forming inner spacers on opposing sidewalls of the sacrificial material between the second nanostructures, wherein the inner spacers mask a second corner of the second nanostructures during the trimming process. Optionally, the first corner is disposed in a first cross-sectional view, wherein the second corner is disposed in a second cross-sectional view that is perpendicular to the first cross-sectional view, and wherein after the trimming process, a curvature of the first corner is greater than a curvature of the second corner. Optionally, the trimming process is performed before forming the sacrificial material between the second nanostructures. Optionally, the trimming process further increases a curvature of a second corner of the second nanostructures, wherein the first corner is disposed in a first cross-sectional view, and wherein the second corner is disposed in a second cross-sectional view that is perpendicular to the first cross-sectional view. Optionally, the trimming process comprises a wet etch process using an etching solution comprising ammonia or H₂O₂. Optionally, the trimming process comprises a wet etch process performed at a temperature in a range of 30° C to 60° C. Optionally, the trimming process comprises a wet etch process performed for a duration of 60 s to 400 s.

In some embodiments, a method includes removing first nanostructures from a plurality of nanostructures to define an opening between second nanostructures of the plurality of nanostructures, wherein the first nanostructures and the second nanostructures are vertically stacked, and wherein removing the first nanostructures leaves impurities on surfaces of the second nanostructures in the opening; removing the impurities from the surfaces of the plurality of nanostructures in the opening with a trimming process; forming a sacrificial material in the opening between the second nanostructures; and replacing the sacrificial material with a gate stack. Optionally, the impurities are disposed at an interface between the sacrificial material and the second nanostructures. Optionally, the method further includes forming inner spacers in the opening between the second nanostructures, wherein the impurities are disposed at an interface between the inner spacers and the second nanostructures. Optionally, the inner spacers mask corner regions of the second nanostructures during the trimming process. Optionally, the impurities are removed prior to forming the sacrificial material. Optionally, the trimming process etches corner regions of the second nanostructures.

In some embodiments, a device includes a first source/drain region and a second source/drain region; a plurality of nanostructures extending between the first source/drain region and the second source/drain region, wherein a first corner of a first nanostructure of the plurality of nanostructures has a first radius in a range of 0.9 nm and 2 nm in a first cross-sectional view; and a gate stack over and around the plurality of nanostructures. Optionally, a top corner of a topmost nanostructure of the plurality of nanostructures has a greater curvature than the first corner of the first nanostructure in the first cross-sectional view, wherein the top corner is disposed above the first corner. Optionally, a second corner of the first nanostructure has a smaller curvature than the first corner of the first nanostructure in a second cross-sectional view, wherein the first cross-sectional view is taken along a longitudinal axis of the gate stack, and wherein the second cross-sectional view is perpendicular to the first cross-sectional view. Optionally, a second corner of the first nanostructure has a second radius in a range of 0.9 nm and 2 nm in a second cross-sectional view, wherein the first cross-sectional view is taken along a longitudinal axis of the gate stack, and wherein the second cross-sectional view is perpendicular to the first cross-sectional view. Optionally, the first nanostructure has a first thickness in the first cross-sectional view and a second thickness in a second cross-sectional view, wherein the first thickness is greater than the second thickness, wherein the first cross-sectional view is taken along a longitudinal axis of the gate stack, and wherein the second cross-sectional view is perpendicular to the first cross-sectional view.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
removing first semiconductor nanostructures from a plurality of semiconductor nanostructures, the plurality of semiconductor nanostructures comprising the first semiconductor nanostructures alternatingly stacked with second semiconductor nanostructures;
after removing the first semiconductor nanostructures, performing a trimming process on the second semiconductor nanostructures, wherein the trimming process increases a curvature of at least a first corner of the second semiconductor nanostructures and removes impurities left from the first semiconductor nanostructures;
forming a sacrificial material between the second semiconductor nanostructures;
forming source/drain regions adjoining the second semiconductor nanostructures in a first cross-sectional view; and
removing the sacrificial material; and
forming a functional gate structure around the second semiconductor nanostructures in a second cross-sectional view different from the first cross-sectional view.

2. The method of claim 1, wherein the trimming process is performed after removing the sacrificial material.

3. The method of claim 2, further comprising:
forming inner spacers on opposing sidewalls of the sacrificial material between the second semiconductor nanostructures, wherein the inner spacers mask a second corner of the second semiconductor nanostructures during the trimming process.

4. The method of claim 3, wherein the first corner is disposed in the second cross-sectional view, wherein the second corner is disposed in the first cross-sectional view, and wherein after the trimming process, a degree of curvature of the first corner is more than a degree of curvature of the second corner.

5. The method of claim 1, wherein the trimming process is performed before forming the sacrificial material between the second semiconductor nanostructures.

6. The method of claim 5, wherein the trimming process further increases a curvature of a second corner of the second semiconductor nanostructures, wherein the first corner is disposed in the second cross-sectional view, and wherein the second corner is disposed in the first cross-sectional view.

7. The method of claim 1, wherein the trimming process comprises a wet etch process using an etching solution comprising hydrogen.

8. The method of claim 1, wherein the trimming process comprises a wet etch process performed at a temperature in a range of 30° C to 60° C.

9. The method of claim 1, wherein the trimming process comprises a wet etch process performed for a duration of 60 s to 400 s.

10. A method comprising:
removing a first nanostructure from a plurality of nanostructures to define an opening between second nanostructures of the plurality of nanostructures, wherein removing the first nanostructure leaves impurities on surfaces of the second nanostructures in the opening;
forming a sacrificial material in the opening between the second nanostructures, wherein the impurities are disposed between the second nanostructures and the sacrificial material;
forming source/drain regions adjoining the second nanostructures;
removing the sacrificial material, wherein removing the sacrificial material exposes the impurities;
performing a trimming process that removes the impurities from the surfaces of the second nanostructures; and
forming a gate stack around the second nanostructures.

11. The method of claim 10, wherein the trimming process increases a vertical distance between sidewalls of the second nanostructures.

12. The method of claim 10, further comprising forming an inner spacer in the opening between the second nanostructures, wherein the impurities are disposed at interfaces between the inner spacer and the second nanostructures.

13. The method of claim 12, wherein the inner spacer masks corner regions of the second nanostructures during the trimming process.

14. The method of claim 12, wherein forming the inner spacer comprises forming the inner spacer on a sidewall of the sacrificial material.

15. The method of claim 10, wherein the trimming process comprises a wet etch process using a hydrogen-comprising etchant.

16. A method comprising:
removing a first nanostructure from a plurality of nanostructures to define an opening between second nanostructures of the plurality of nanostructures;
forming a sacrificial material in the opening between the second nanostructures;
forming an inner spacer on a sidewall of the sacrificial material and between the second nanostructures;
forming source/drain regions adjoining the second nanostructures;
removing the sacrificial material;
performing a trimming process that increases a curvature of first corners of the second nanostructures in a first cross-sectional view while the inner spacer masks second corners of the second nanostructures in a second cross-sectional view that is perpendicular to the first cross-sectional view; and
forming a gate stack around the second nanostructures.

17. The method of claim 16, wherein after the trimming process, the first corners have a greater degree of curvature than the second corners.

18. The method of claim 16, wherein removing the first nanostructure leaves impurities on the second nanostructures, and wherein the trimming process at least partially removes the impurities from exposed surfaces of the second nanostructures.

19. The method of claim 18, wherein after the trimming process, a portion of the impurities remains between the inner spacer and the second nanostructures.

20. The method of claim 16, wherein after the trimming process, a vertical distance between lines that are tangent to the first corners of the second nanostructures increases in a direction away from the second nanostructures.
